(19) United States
(12) Patent Application Publication
(10) Pub. No.: US 2023/0402474 A1
(43) Pub. Date: Dec. 14, 2023

(54) ELECTRONIC DEVICE AND METHOD OF MANUFACTURING THEREOF

(71) Applicant: ROHM CO., LTD., Kyoto (JP)

(72) Inventor: Eiji KUWAHARA, Kyoto (JP)

(73) Assignee: ROHM CO., LTD., Kyoto (JP)

(21) Appl. No.: 18/332,698

(22) Filed: Jun. 9, 2023

(30) Foreign Application Priority Data
Jun. 14, 2022 (JP) 2022-095663

(51) Int. Cl. H01L 27/146

(52) U.S. Cl. CPC H01L 27/14621; H01L 27/14632; H01L 27/14687; H01L 27/14685

(57) ABSTRACT

The present disclosure provides an electronic device. The electronic device includes a first inorganic film, a second inorganic film covering the first inorganic film, and an opening. The opening is formed in the second inorganic film to partially expose the first inorganic film. The opening has a wall surface curved in a wavy line shape in a plan view.

### TECHNICAL FIELD

The disclosure relates to an electronic device and a method of manufacturing thereof.

### BACKGROUND

Patent document 1 discloses a method for manufacturing a semiconductor apparatus, the method including a step of patterning a patterning film by means of lifting.

### PRIOR ART DOCUMENT

### Patent Document

[Patent document 1] Japan Patent Publication No. 2013-29670

### BRIEF DESCRIPTION OF THE DRAWINGS

FIG. 1 is a plan view of an electronic device of a first embodiment.

FIG. 2 is an enlarged plan view of a light receiving region shown in FIG. 1.

FIG. 3 is a sectional view taken along the line III-III in FIG. 2.

FIG. 4 is an enlarged sectional view of a region including the opening shown in FIG. 2.

FIG. 5 is an enlarged plan view of a main portion of the opening shown in FIG. 3.

FIG. 6A is a sectional view of a part of a method of manufacturing the electronic device shown in FIG. 1.

FIG. 6B is a sectional view of a next step after FIG. 6A.

FIG. 6C is a sectional view of a next step after FIG. 6B.

FIG. 6D is a sectional view of a next step after FIG. 6C.

FIG. 6E is a sectional view of a next step after FIG. 6D.

FIG. 7 is an enlarged plan view of the layout of the resist film shown in FIG. 6C.

FIG. 8 is an enlarged plan view of a main portion of the resist film shown in FIG. 7.

FIG. 9 is an enlarged sectional view of the resist film shown in FIG. 7.

FIG. 10A is an enlarged plan view for illustrating a step of forming an opening.

FIG. 10B is an enlarged plan view for illustrating a step of forming an opening.

FIG. 10C is an enlarged plan view for illustrating a step of forming an opening.

FIG. 10D is an enlarged plan view for illustrating a step of forming an opening.

FIG. 11A is an enlarged sectional view for illustrating a step of forming an opening.

FIG. 11B is an enlarged sectional view for illustrating a step of forming an opening.

FIG. 11C is an enlarged sectional view for illustrating a step of forming an opening.

FIG. 11D is an enlarged sectional view for illustrating a step of forming an opening.

FIG. 12 is an enlarged plan view of a reference resist film.

FIG. 13 is an enlarged sectional view of a manufacturing step using the reference resist film.

FIG. 14 is a sectional view of a main portion of an electronic device of a second embodiment.

FIG. 15 is an enlarged sectional view of a region including the opening shown in FIG. 14.

FIG. 16 is an enlarged sectional view of a step of forming the second inorganic film shown in FIG. 14.

FIG. 17 is an enlarged plan view of a main portion of an electronic device of a third embodiment.

FIG. 18 is a sectional view taken along the line XVIII-XVIII in FIG. 17.

FIG. 19 is an enlarged plan view of a main portion of an opening of a first variation example.

FIG. 20 is an enlarged plan view of a main portion of an opening of a second variation example.

FIG. 21 is an enlarged plan view of a main portion of an opening of a third variation example.

### DETAILED DESCRIPTION OF THE EMBODIMENTS

Embodiments are described in detail with reference to the accompanying drawings below. These accompanying drawings are schematic and are not strictly depicted according to equivalent or actual scales. The corresponding structures among these accompanying drawings are denoted by the same reference symbols or numerals, and the repeated details are omitted or simplified. The structures with omitted or simplified details are used for omitting or simplifying the details previously described.

In an expression such as “substantially equal to” in the description concerning a comparison target, the expression includes a numerical value (form) equivalent to the numerical value (form) of the comparison target, and further includes a numerical error (form error) within a range of ±10% of the numerical value (form) of the comparison target used as a reference. Terms such as “first”, “second” and “third” are used in the embodiments, and these terms are merely denotations given to the names of the structures to clarify the order of descriptions and are not for limiting the names of the structures.

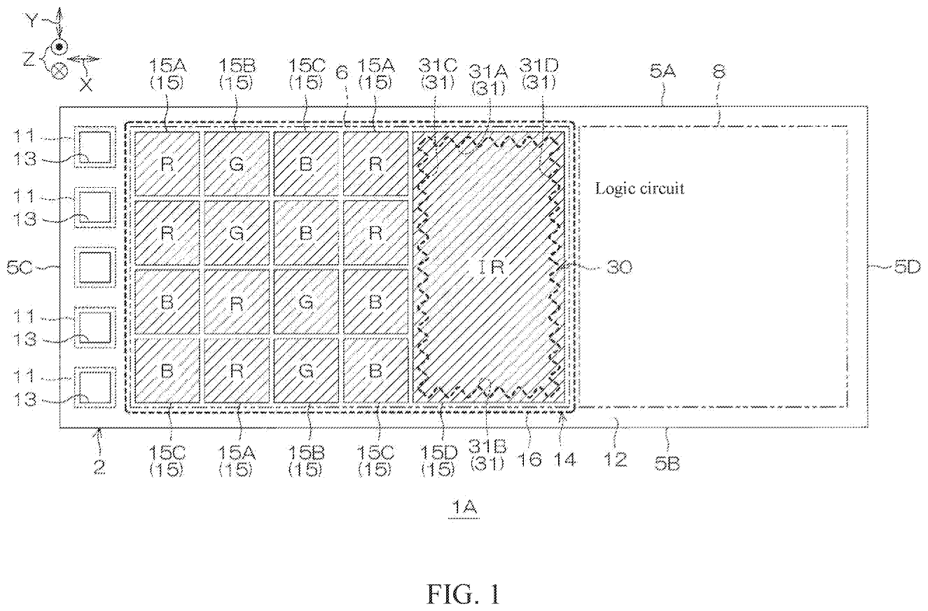

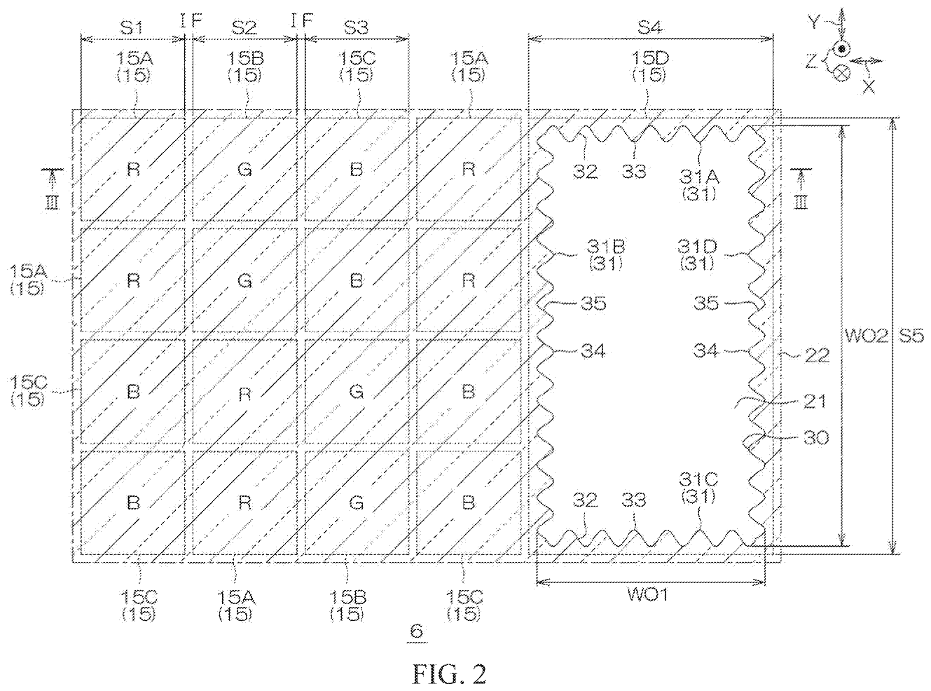

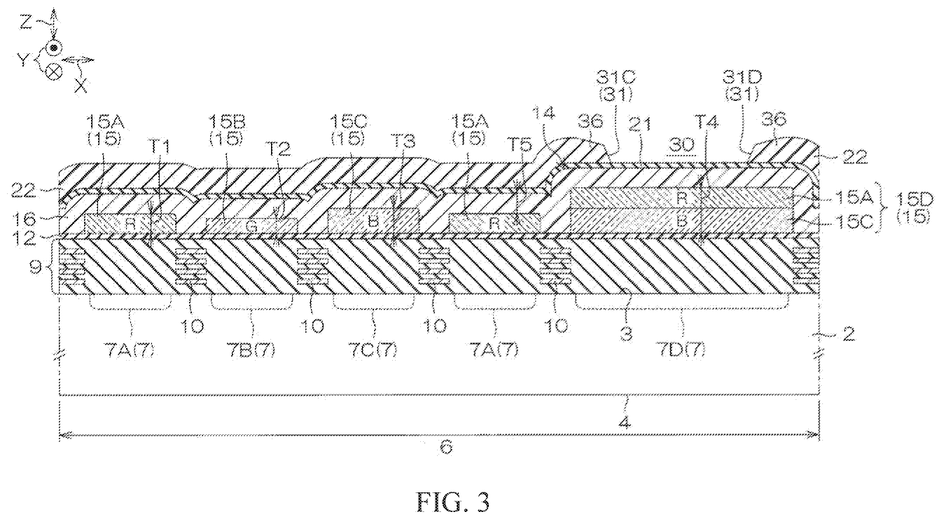

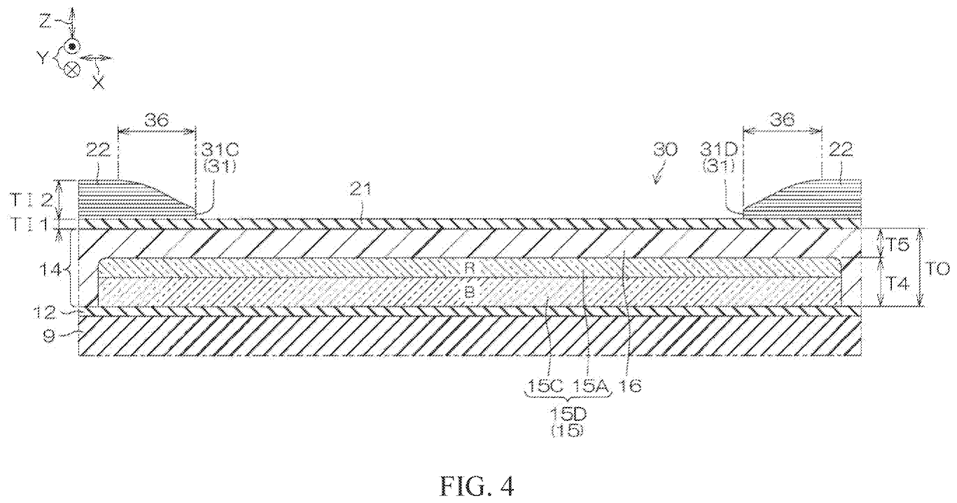

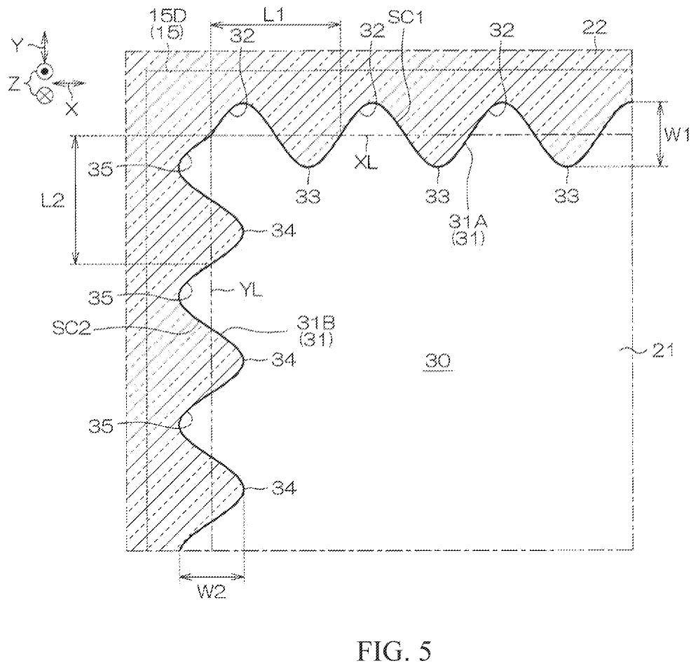

FIG. 1 shows a plan view of an electronic device 1A of a first embodiment. FIG. 2 shows an enlarged plan view of a light receiving region 6 shown in FIG. 1. FIG. 3 shows a sectional view taken along the line III-III in FIG. 2. FIG. 4 shows an enlarged sectional view of a region including an opening 30 shown in FIG. 2. FIG. 5 shows an enlarged plan view of a main portion of the opening 30 shown in FIG. 3.

The electronic device 1A is an illuminance sensor (semiconductor light receiving apparatus) that detects light. For example, in order to control the display brightness of a display device such as a television, a computer, a vehicle navigation system and a tablet terminal (such as a smartphone), the illuminance sensor is assembled to a sensor circuit portion of the display device.

Referring to FIG. 1 to FIG. 5, in this embodiment, the electronic device 1A includes a chip 2 is shaped as rectangle. The chip 2 is formed by a silicon chip (semiconductor chip) including silicon single crystals. The chip 2 may also be formed by a wide bandgap semiconductor chip (for example, a GaN chip or a SiC chip) including wide bandgap semiconductor single crystals.

The chip 2 includes a first main surface 3 on one side, a second main surface 4 on the other side, and first to fourth side surfaces 5A to 5D connecting the first main surface 3 and the second main surface 4. The first main surface 3 and the second main surface 4 are shaped as quadrilaterals (specifically, rectangles) in a plan view when observed in a normal direction Z thereof (hereinafter referred to as “in the plan view”). The chip 2 may also be shaped as a square in the plan view.

The first side surface 5A and the second side surface 5B extend in a first direction X of the first main surface 3, and are opposite in a sec and direction Y intersecting (specifically, orthogonal to) the first direction X. The first side surface 5A and the second side surface 5B form long sides of the chip2. The third side surface 5C and the fourth side surface 5D extend in the second direction Y, and are opposite in the first direction X. The third side surface 5C and the fourth side surface 5D form short sides of the chip 2.

The electronic device 1A includes a light receiving region 6 provided on the first main surface 3. The light receiving region 6 in the plan view is provided on one side in the lengthwise direction of the first main surface 3 (on the side of the third side surface 5C). The light receiving region 6 includes at least one (multiple in this embodiment) light receiving device 7 (functional device) that converts incident light from the outside to a current. Multiple light receiving devices 7 are depicted in a simplified form by dotted lines in the figures such as FIG. 3.

The multiple light receiving devices 7 are formed electrically independently on the chip 2 (the first main surface 3) so as to independently generate currents corresponding to the incident light. The multiple light receiving devices 7 are formed by means of using a surface layer portion of the first main surface 3 or a region on the first main surface 3. The multiple light receiving devices 7 may also include at least one of a photodiode and a phototransistor.

In this embodiment, the multiple light receiving devices 7 are arranged at intervals in the first direction X and the second direction Y in the plan view. In this embodiment, 16 light receiving devices 7 are in arranged in an array of four rows and four columns in the plan view, and one light receiving device 7 with respect to a device group including the 16 light receiving devices 7 is arranged on the other side of the lengthwise direction of the first main surface 3 (the side of the fourth side surface 5D). The layout (the number, arrangement positions and planar area) of the light receiving devices 7 can be adjusted as appropriate according to the wavelength region of the incident light to be detected and the detection precision of the incident light.

In this embodiment, the multiple light receiving devices 7 include at least one (multiple in this embodiment) first light receiving device 7A detecting a first wavelength region λ1 of red light, at least one (multiple in this embodiment) second light receiving device 7B detecting a second wavelength region λ2 of green light, at least one (multiple in this embodiment) third light receiving device 7C detecting a third wavelength region λ3 of blue light, and at least one (one in this embodiment) fourth light receiving device 7D detecting a fourth wavelength region λ4 of infrared light.

The first light receiving device 7A generates a current corresponding to red light. The second light receiving device 7B generates a current corresponding to green light. The third light receiving device 7C generates a current corresponding to blue light. The fourth light receiving device 7D generates a current corresponding to infrared light. The current generated in the fourth light receiving device 7D may also be used as a reference current with respect to the currents generated in the first to third light receiving devices 7A to 7C.

The multiple first light receiving devices 7A are arranged in the first column and the fourth column of the first row and the second row, and the second columns of the third row and the fourth row. The multiple second light receiving devices 7B are arranged in the second columns of the first row and the second row, and the third columns of the third row and the fourth row. The multiple third light receiving devices 7C are arranged in the third columns of the first row and the second row, and the first column and the fourth column of the third row and the fourth row.

The fourth light receiving device 7D is arranged on the other side in the lengthwise direction of the first main surface 3 (the side of the fourth side surface 5D) with respect to the device group including the first to third light receiving devices 7A to 7C, and is disposed opposite to the device group in the first direction X. The fourth light receiving device 7D has a planar area greater than planar areas of the first to third light receiving devices 7A to 7C.

The electronic device 1A includes a circuit region 8 on the first main surface 3, wherein the circuit region 8 is disposed in a region different from the light receiving region 6. The circuit region 8 is disposed on the other side in the lengthwise direction of the first main surface 3 (the side of the fourth side surface 5D) with respect to the light receiving region 6 in the plan view, and is disposed opposite to the light receiving region 6 in the first direction X. The circuit region 8 includes a logic circuit. The logic circuit is configured to be electrically connected to the light receiving devices 7 to convert the currents of the light receiving devices 7 to output signals corresponding to the component of the incident light. The logic circuit may be formed by an electronic circuit including an insulated gate transistor (for example, complementary metal oxide semiconductor (CMOS)).

The electronic device 1A includes an interlayer insulating film 9 covering the first main surface 3. The interlayer insulating film 9 covers the multiple light receiving devices 7 in the light receiving region 6, and covers the logic circuit in the circuit region 8. The interlayer insulating film 9 preferably has a flat insulating main surface. The interlayer insulating film 9 may also have insulating sidewalls connected to the first to fourth side surfaces 5A to 5D of the chip 2.

In this embodiment, the interlayer insulating film 9 has a laminated structure including multiple laminated insulating films. The multiple insulating films may include at least one of silicon oxide films and silicon nitride films. In this embodiment, the interlayer insulating film 9 has a laminated structure including multiple silicon oxide films. The thickness (total thickness) of the interlayer insulating film 9 is, for example, between 1 micrometer (μm) and 10 μm. The thickness of the interlayer insulating film 9 is preferably between 4 μm and 8 μm.

The electronic device 1A includes multiple wirings 10 arranged in the interlayer insulating film 9. The multiple wirings 10 are arranged in multiple lamination section s through multiple via electrodes (not shown) and thus form multiple layers of wirings in the interlayer insulating film 9. The multiple wirings 10 are routed in a region among the multiple light receiving devices 7 so as to promote light to be incident toward the multiple light receiving devices 7.

That is to say, the multiple wirings 10 expose the multiple light receiving devices 7 in the plan view. The multiple wirings 10 are selectively electrically connected to the multiple light receiving devices 7 and the logic circuit. The multiple wirings 10 include the wirings 10 that transmit the currents generated in the multiple light receiving devices 7 to the logic circuit. The multiple wirings 10 further include wirings 10 that transmit electrical signals from the outside to the multiple light receiving devices 7 or the logic circuit. Moreover, the multiple wirings 10 also include wirings 10 that transmit output signals generated in the logic circuit to other regions.

The electronic device 1A includes multiple pad electrodes 11 arranged in the interlayer insulating film 9. The multiple pad electrodes 11 form uppermost-layer wirings of the multi-layer wiring structure, respectively. The pad electrodes 11 may be regarded as a constituent of the multiple wirings 10. In this embodiment, the multiple pad electrodes 11 are provided on the side in the lengthwise direction of the first main surface 3 (the side of the third side surface 5C) with respect to the light receiving region 6 in the plan view.

The multiple pad electrodes 11, in the plan view, are arranged at intervals in the second direction Y, and are opposite to the circuit region 8 with the light receiving region 6 in between in the first direction X. The multiple pad electrodes 11 are respectively shaped as polygons (quadrilaterals in this embodiment) in the plan view. The multiple pad electrodes 11 are respectively electrically connected to the corresponding wirings 10 in the interlayer insulating film 9 through via electrodes (not shown).

Each pad electrode 11 may be a structure that is connected to one wiring 10 extending linearly, wherein the linear wiring 10 is connected to a via electrode. The multiple pad electrodes 11 transmit electrical signals from the outside to the logic circuit through the corresponding wirings 10, and transmit output signals from the logic circuit to the outside through the corresponding wirings 10.

The electronic device 1A includes a base inorganic insulating film 12 covering the interlayer insulating film 9. The base inorganic insulating film 12 may include at least one of a silicon oxide films and a silicon nitride film. The base inorganic insulating film 12 is preferably formed by an insulator different from the interlayer insulating film 9 (specifically the uppermost-layer insulating film of the interlayer insulating film 9). In this embodiment, the base inorganic insulating film 12 has a single-layer structure formed by a silicon nitride film.

The base inorganic insulating film 12 preferably covers the entire insulating main surface of the interlayer insulating film 9. The base inorganic insulating film 12 preferably has a flat insulating main surface. The base inorganic insulating film 12 may also have insulating sidewalls connected to the first to fourth side surfaces 5A to 5D of the chip 2. The thickness of the base inorganic insulating film 12 may be between 0.1 μm and 2 μm. The thickness of the base inorganic insulating film 12 is preferably between 0.5 μm and 1.5 μm.

The electronic device 1A includes multiple pad openings 13 that expose the multiple pad electrodes 11. The multiple pad openings 13 pass through the base inorganic insulating film 12 and a portion of the interlayer insulating film 9 to expose the multiple pad electrodes 11. That is, wall surfaces of the multiple pad openings 13 are obtained by defining the base inorganic insulating film 12 and a portion of the interlayer insulating film 9. The multiple pad openings 13 are respectively shaped as polygons (quadrilaterals in this embodiment) in the plan view. The multiple pad electrodes 11 are connected to lead wires such as bonding wires through the multiple pad openings 13.

The electronic device 1A includes an organic film 14 formed on the base inorganic insulating film 12. More specifically, the organic film 14 is formed by an organic insulating film. In this embodiment, the organic film 14 has a laminated structure including multiple colored transparent color filter films 15 (colored transparent resin films) and a colorless transparent filter film 16 (a colorless transparent resin film).

The multiple color filter films 15 are respectively formed by colored transparent resin films containing a coloring material (pigment). The multiple color filter films 15 may include at least one of polyimide films, polyamide films, polybenzoxazole films, acrylic films and gelatin films.

The layout (the number, arrangement positions and planar areas) of the color filter films 15 can be adjusted as appropriate according to the wavelength region of the incident light to be detected and the detection precision of the incident light. The multiple color filter films 15 are arranged at intervals in the first direction X and the second direction Y in the plan view to be opposite to the multiple light receiving devices 7 in one-to-one correspondence in the thickness direction of the interlayer insulating film 9. In this embodiment, 16 color filter films 15 are in arranged in an array of four rows and four columns in the plan view, and one color filter film 15 with respect to a filter group including the 16 color filter films 15 is arranged on the other side in the lengthwise direction of the first main surface 3 (the side of the fourth side surface 5D).

In this embodiment, the multiple color filter films 15 include at least one (multiple in this embodiment) first color filter film 15A, at least one (multiple in this embodiment) second color filter film 15B, at least one (multiple in this embodiment) third color filter film 15C, and at least one (one in this embodiment) fourth color filter film 15D.

The first color filter film 15A has an appearance in red to allow the first wavelength region λ1 of red light to pass through and to attenuate the second wavelength region λ2 of green light and the third wavelength region λ3 of blue light. The second color filter film 15B has an appearance in green to allow the second wavelength region λ2 of green light to pass through and to attenuate the first wavelength region λ1 and the third wavelength region λ3.

The third color filter film 15C has an appearance in blue to allow the third wavelength region λ3 of blue light to pass through and to attenuate the first wavelength region λ1 and the second wavelength region λ2. The fourth color filter film 15D has an appearance in black to allow the fourth wavelength region λ4 of infrared light to pass through and to attenuate the first wavelength region λ1, the second wavelength region λ2 and the third wavelength region λ3.

The multiple first color filter films 15A are arranged in the first column and the fourth column of the first row and the second row and the second columns of the third row and the fourth row, and are opposite to the multiple first light receiving devices 7A in one-to-one correspondence in the thickness direction of the interlayer insulating film 9. The multiple second color filter films 15B are arranged in the second columns of the first row and the second row and the third columns of the third row and the fourth row, and are opposite to the multiple second light receiving devices 7B in one-to-one correspondence in the thickness direction of the interlayer insulating film 9.

The multiple third color filter films 15C are arranged in the third columns of the first row and the second row and the first column and the fourth column of the third row and the fourth row, and are opposite to the multiple third light receiving devices 7C in one-to-one correspondence in the thickness direction of the interlayer insulating film 9. The fourth color filter film 15D is arranged on the other side in the lengthwise direction of the first main surface 3 (the side of the fourth side surface 5D) with respect to the filter group including the first to the third color filter films 15A to 15C, and is disposed opposite to the fourth light receiving device 7D in one-to-one correspondence in the thickness direction of the interlayer insulating film 9.

The first to third color filter films 15A to 15C are respectively shaped as quadrilaterals (squares in this embodiment) in the plan view. However, the first to third color filter films 15A to 15C may also be shaped as rectangles extending in the first direction X or the second direction Y.

In the first direction X, the first color filter films 15A have a first size S1, the second color filter films 15B have a second size S2, and the third color filter films 15C have a third size S3. The first to third sizes S1 to S3 may be substantially equal to one another or be different from one another.

The first to third sizes S1 to S3 may be between 10 μm and 200 μm. The first to third sizes S1 to S3 are preferably between 50 μm and 100 μm. A filter interval IF among the multiple first to third color filter films 15A to 15C may be between 1 μm and 20 μm. The filter interval IF is preferably between 5 μm and 15 μm.

The first color filter films 15A have a first thickness T1, the second color filter films 15B have a second thickness T2, and the third color filter films 15C have a third thickness T3. The first to third thicknesses T1 to T3 may be substantially equal to one another or be different from one another. In this embodiment, the second thickness T2 is less than the first thickness T1, and the third thickness T3 is greater than the second thickness T2. The third thickness T3 may also be substantially equal to the first thickness T1.

The first thickness T1 may be between 1 μm and 5 μm. The first thickness T1 is preferably between 1.5 μm and 2.5 μm. The second thickness T2 may be between 0.1 μm and 2 μm. The second thickness T2 is preferably between 0.5 μm and 1.5 μm. The third thickness T3 may be between 1 μm and 5 μm. The third thickness T3 is preferably between 1.5 μm and 2.5 μm.

The fourth color filter film 15D is shaped as a quadrilateral (a rectangle extending in the second direction Y in this embodiment) in the plan view, and is disposed opposite to the filter group including the first to third color filter films 15A to 15C in the first direction X. However, the fourth color filter film 15D may also be shaped as a square. The fourth color filter film 15D is arranged at an interval of the filter interval IF from the filter group including the first to third color filter films 15A to 15C.

The fourth color filter film 15D has a fourth size S4 in the first direction X and a fifth size S5 in the second direction Y. The fourth size S4 is preferably greater than the first to third sizes S1 and S3. The fourth size S4 may be between one time and ten times the first to third sizes S1 to S3. The fourth size S4 is preferably greater than two times the first to third sizes S1 to S3. The fourth size S4 may be between 50 μm and 500 μm. The fourth size S4 is preferably between 100 μm and 300 μm.

The fifth size S5 is greater than the fourth size S4. The fifth size S5 may be between one time and four times the fourth size S4. However, the fifth size S5 may also be less than the fourth size S4. In this case, the fifth size S5 is preferably greater than one-half of the fourth size S4. A planar area of the fourth color filter film 15D is preferably greater than an opening area of each pad opening 13. The planar area of the fourth color filter film 15D is preferably greater than planar areas of the first to third color filter films 15A to 15C.

The fourth color filter film 15D has a fourth thickness T4. The fourth thickness T4 may be greater than the first to third thicknesses T1 to T3, or may be less than the first to third thicknesses T1 to T3. In this embodiment, the fourth thickness T4 is greater than the first to third thicknesses T1 to T3. The fourth thickness T4 may be between 2 μm and 10 μm. The fourth thickness T4 is preferably between 3 μm and 5 μm.

In this embodiment, the fourth color filter film 15D has a laminated structure including the third color filter films 15C and the first color filter films 15A sequentially laminated from the side of the base inorganic insulating film 12. Thus, the fourth thickness T4 is the sum of the first thickness T1 and the third thickness T3.

However, the fourth color filter film 15D may also have a laminated structure including the first color filter films 15A and the third color filter films 15C sequentially laminated from the side of the base inorganic insulating film 12. The fourth color filter film 15D may further have a single-layer structure formed by one single resin film.

The transparent filter film 16 is formed by a colorless transparent resin film without any coloring material (pigment). The transparent filter film 16 may include at least one of a polyimide film, a polyamide film, a polybenzoxazole film, an acrylic film and a gelatin film. The transparent filter film 16 covers the multiple color filter films 15 (the first to fourth color filter films 15A to 15D) on the base inorganic insulating film 12 all at once. The transparent filter film 16 covers the base inorganic insulating film 12 to expose the multiple pad openings 13.

In this embodiment, the transparent filter film 16 covers the light receiving region 6 in the plan view but exposes the circuit region 8. However, the transparent filter film 16 may also cover the circuit region 8 in the plan view. In this case, the transparent filter film 16 may have organic sidewalls connected to the first to fourth side surfaces 5A to 5D of the chip 2. The transparent filter film 16 has a fifth thickness T5. The fifth thickness T5 may be between 1 μm and 5 μm. The fifth thickness T5 is preferably between 2 μm and 4 μm.

An organic thickness TO (total thickness) of the organic film 14 becomes the sum of any one of the first to fourth thicknesses T1 to T4 and the fifth thickness T5. In this embodiment, the organic thickness TO is defined by the sum of the thickest fourth thickness T4 and the fifth thickness T5.

The electronic device 1A includes a first inorganic film 21 covering the organic film 14. The first inorganic film 21 is formed by a colorless transparent inorganic insulating film, and has a modulus of elasticity greater than a modulus of elasticity of the organic film 14. The first inorganic film 21 may include at least one of a silicon oxide film and a silicon nitride film. In this embodiment, the first inorganic film 21 has a single-layer structure formed by a silicon oxide film.

The first inorganic film 21 covers a global outer surface of the transparent filter film 16. The first inorganic film 21 may also cover the base inorganic insulating film 12 in a region other than the organic film 14. The first inorganic film 21 may expose the circuit region 8 in the plan view. However, the first inorganic film 21 may also cover the circuit region 8 in the plan view. In this case, the first inorganic film 21 may have inorganic sidewalls connected to the first to fourth side surfaces 5A to 5D of the chip 2.

The first inorganic film 21 has a first inorganic thickness TI1. The first inorganic thickness TI1 is less than the organic thickness TO of the organic film 14. The first inorganic thickness TI1 may also be less than the fifth thickness T5 of the transparent filter film 16. The first inorganic thickness TI1 may also be less than the fourth thickness T4 of the fourth color filter film 15D. The first inorganic thickness TI1 may further be less than the first to third thicknesses T1 to T3.

The first inorganic film 21 may also have a thickness between 0.05 μm and 2 μm. The thickness of the first inorganic film 21 may be between 0.05 μm and 0.1 μm, between 0.1 μm and 0.5 μm, between 0.5 μm and 1 μm, between 1 μm and 1.5 μm, or between 1.5 μm and 2 μm. The thickness of the first inorganic film 21 is preferably between 0.2 μm and 1.5 μm.

The electronic device 1A includes a second inorganic film 22 covering the first inorganic film 21. The second inorganic film 22 is formed by a colorless transparent inorganic insulating film, and has a modulus of elasticity greater than the modulus of elasticity of the organic film 14. In this embodiment, the second inorganic film 22 is formed as an optical filter film that selectively attenuates light of a specific wavelength region (any one of the first to fourth wavelength regions λ1 to λ4).

In this embodiment, the second inorganic film 22 has a laminated structure, which is obtained by laminating multiple inorganic films having different refractive indices. Specifically, the second inorganic film 22 has a laminated structure including a silicon oxide film and a titanium oxide film. More specifically, the second inorganic film 22 has a multi-layer laminated structure obtained by alternately laminating multiple silicon oxide films and multiple titanium oxide films.

The number of laminated layers and the thicknesses of the silicon oxide films and titanium oxide films can be adjusted according to the wavelength region that is to be attenuated. The total number of laminated layers of the silicon oxide films and titanium oxide films is preferably less than 50. The thickness of the silicon oxide film may be between 10 nm and 200 nm. The thickness of the titanium oxide film may be between 10 nm and 200 nm.

In this embodiment, the second inorganic film 22 is formed as an infrared cutoff filter film that selectively attenuates the fourth wavelength region λ4 of infrared light, and covers the first to third color filter films 15A to 15C in the plan view. However, the second inorganic film 22 can also be formed as a visible light cutoff filter film that selectively attenuates at least one of the first to third wavelength regions λ1 to λ3, so as to selectively expose at least one of the first to fourth color filter films 15A to 15D.

The second inorganic film 22 may expose the circuit region 8 in the plan view. However, the second inorganic film 22 may also cover the circuit region 8 in the plan view. In this case, the second inorganic film 22 may have inorganic sidewalls connected to the first to fourth side surfaces 5A to 5D of the chip 2.

The second inorganic film 22 has a second inorganic thickness TI2 (total thickness). In this embodiment, the second inorganic thickness TI2 is greater than the thickness of the first inorganic film 21. However, the second inorganic thickness TI2 may also be less than the thickness of the first inorganic film 21. In this embodiment, the second inorganic thickness TI2 is less than the thickness (total thickness) of the organic film 14. However, the second inorganic thickness TI2 may also be greater than the thickness of the organic film 14.

The second inorganic thickness TI2 may be between 1 μm and 15 μm. The second inorganic thickness TI2 may be 1 μm and 2.5 μm, between 2.5 μm and 5 μm, between 5 μm and 7.5 μm, between 7.5 μm and 10 μm, between 10 μm and 12.5 μm, or between 12.5 μm and 15 μm. The second inorganic thickness TI2 is preferably between 3 μm and 7 μm.

The electronic device 1A includes an opening 30 formed in the second inorganic film 22 to expose the first inorganic film 21 (inorganic insulating film). The opening 30 may be regarded as a constituent of the second inorganic film 22. In this embodiment, the opening 30 is formed as a light extraction opening that allows all wavelength regions of incident light to pass through. That is, the opening 30 is not the pad opening 13 that exposes the pad electrode 11 (electrode).

In this embodiment, the opening 30 exposes a portion of the first inorganic film 21 covering the fourth color filter film 15D. Thus, infrared light (the fourth wavelength region λ4) toward the first to third color filter films 15A to 15C is attenuated by the second inorganic film 22, and infrared light (the fourth wavelength region λ4) toward the fourth color filter film 15D is incident on the fourth color filter film 15D through the opening 30.

In this embodiment, the opening 30 exposes a region surrounded by the periphery of the fourth color filter film 15D at a distance inwardly from the periphery of the fourth color filter film 15D in the plan view. That is, a portion defined as the opening 30 from the second inorganic film 22 entirely and globally covers the periphery of the fourth color filter film 15D in the plan view. The opening 30 is defined to be shaped as a polygon in the plan view. In this embodiment, the opening 30 is defined to be shaped as a quadrilateral (specifically a rectangle extending in the second direction Y) in the plan view.

The opening 30 has a first opening width WO1 in the first direction X and a second opening width WO2 in the second direction Y. The first opening width WO1 is greater than the pad opening width of each pad opening 13. The first opening width WO1 is greater than the first to third sizes S1 to S3 (between 10 μm and 200 μm), and less than the fourth size S4 (between 50 μm and 500 μm). That is, the first opening width WO1 is between 10 μm and 500 μm.

The first opening width WO1 may be between 10 μm and 50 μm, between 50 μm and 100 μm, between 100 μm and 150 μm, between 150 μm and 200 μm, between 200 μm and 250 μm, between 250 μm and 300 μm, between 300 μm and 350 μm, between 350 μm and 400 μm, between 400 μm and 450 μm or between 450 μm and 500 μm. The first opening width WO1 is preferably greater than 50 μm. The first opening width WO1 is preferably less than 300 μm.

The second opening width WO2 is greater than the first opening width WO1. The second opening width WO2 is less than the fifth size S5. The second opening width WO2 may be between one time and fourth times of the first opening width WO1. However, the second opening width WO2 may also be less than the first opening width WO1. In this case, the second opening width WO2 is preferably greater than one-half the first opening width WO1. An opening area of the opening 30 is preferably greater than an opening area of each pad opening 13. The opening area of the opening 30 is preferably greater than the planar areas of the first to third color filter films 15A to 15C, and less than the planar area of the fourth color filter film 15D.

The opening 30 has a wall surface 31 defined from the second inorganic film 22. Specifically, the wall surface 31 is formed by defining a portion or all of a plurality of inorganic films forming the second inorganic film 22. In this embodiment, the wall surface 31 is obtained by defining an insulating laminated structure including a plurality of inorganic films (multiple silicon oxide films and multiple titanium oxide films) forming a portion of the second inorganic film 22. In this embodiment, the w all surface 31 extends along the periphery of the fourth color filter film 15D in the plan view.

In this embodiment, the wall surface 31 includes first to fourth wall surfaces 31A to 31D. The first wall surface 31A extends in the first direction X in the plan view, and forms a short side of the opening 30. The first wall surface 31A has an end on one side in the first direction X and the other end on the other side in the first direction X.

The second wall surface 31B extends from one end of the first wall surface 31A in the second direction Y in the plan view, and forms a long side of the opening 30. The second wall surface 31B has an end on one side in the second direction Y and the other end on the other side in the second direction Y. One end of the second wall surface 31B and one end of the first wall surface 31A form one opening corner.

The third wall surface 31C extends from the other end of the second wall surface 31B in the first direction X in the plan view, and forms the short side of the opening 30. The third wall surface 31C is opposite to the first wall surface 31A in the second direction Y. The third wall surface 31C has an end on one side in the first direction X and the other end on the other side in the first direction X. One end of the third wall surface 31C and the other end of the second wall surface 31B form one opening corner.

The fourth wall surface 31D extends in a region between the other end of the first wall surface 31A and the other end of the third wall surface 31C in the second direction Y in the plan view, and forms the long side of the opening 30. The fourth wall surface 31D is opposite to the second wall surface 31B in the first direction X. The fourth wall surface 31D has an end on one side in the second direction Y and the other end on the other side in the second direction Y. One end of the fourth wall surface 31D and the other end of the first wall surface 31A form one opening corner, and the other end of the fourth wall surface 31D and the other end of the third wall surface 31C form one opening corner.

Referring to FIG. 1, FIG. 2 and FIG. 5, the opening 30 has a portion curved in a wavy line shape in at least one of the first to fourth wall surfaces 31A to 31D. In this embodiment, the opening 30 has a portion curved in a wavy line shape in all of the first to fourth wall surfaces 31A to 31D. That is, the wall surface 31 of the opening 30 entirely and globally curves in a wavy line shape in the plan view. The structure of the first wall surface 31A and the structure of the second wall surface 31B are to be specifically described below.

The first wall surface 31A is formed to extend in the first direction X in the plan view, and curves in a wavy line shape toward one side (the outside of the opening 30) in the second direction Y and the other side (the inside of the opening 30) in the second direction Y. More specifically, the first wall surface 31A, in the plan view, includes at least one (multiple in this embodiment) first recess portion 32 recessed in an arc toward one side in the second direction Y, and at least one (multiple in this embodiment) first protrusion portion 33 protruding in an arc toward the other side in the second direction Y. The first protrusion portion 33 and the first recess portion 32 are adjacent in the first direction X. More specifically, multiple first protrusion portions 33 and multiple first recess portions 32 are formed alternately in the first direction X.

When a first imaginary line XL connecting one end and the other end of the first wall surface 31A in the first direction X is set, the multiple first recess portions 32 recess toward one side in the second direction Y with respect to the first imaginary line XL and the multiple first protrusion portions 33 protrude toward the other side in the second direction Y with respect to the first imaginary line XL. A protrusion width of the first protrusion portion 33 in the second direction Y by using the first imaginary line XL as a reference is preferably substantially equal to a recess width of the first recess portion 32 in the second direction Y by using the first imaginary line XL as a reference.

Thus, the first wall surface 31A in the plan view forms as a wavy line shape that depicts a first sinusoidal curve SC1. That is, the multiple first recess portions 32 respectively form multiple valleys of the first sinusoidal curve SC1, and the multiple first protrusion portions 33 respectively form multiple hills of the first sinusoidal curve SC1.

In this embodiment, one end and the other end of the first wall surface 31A are formed by the first recess portions 32 (that is, the valleys of the first sinusoidal curve SC1). One end and the other end of the first wall surface 31A are preferably set as zero points (starting points of the recess of the first recess portion 32) of the first sinusoidal curve SC1.

In this embodiment, the first wall surface 31A has a constant first wavelength L1 in the plan view. The first wavelength L1 is defined by a distance of a portion of the first wall surface 31A in the first direction X, wherein the portion includes the first recess portion 32 and the first protrusion portion 33 adjacent to each other. The first wavelength L1 may also be defined by a distance between the centers of two adjacent first recess portions 32 in the first direction X, or a distance between the centers of two adjacent first protrusion portions 33 in the first direction X.

The first wavelength L1 may be between 5 μm and 100 μm. The first wavelength L1 may also be between 5 μm and 25 μm, between 25 μm and 50 μm, between 50 μm and 75 μm, or between 75 μm and 100 μm. The first wavelength L1 is preferably between 20 μm and 60 μm.

In this embodiment, the first wall surface 31A has a constant first amplitude W1 in the plan view. The first amplitude W1 is defined by a distance between the center of the first recess portion 32 and the center of the first protrusion portion 33 in the second direction Y. The first amplitude W1 may also be a sum of the protrusion width and the recess width.

The first amplitude W1 may be between 1 μm and 50 μm. The first amplitude W1 may also be between 1 μm and 10 μm, between 10 μm and 20 μm, between 20 μm and 30 μm, between 30 μm and 40 μm, or between 40 μm and 50 μm. The first amplitude W1 is preferably between 5 μm and 25 μm.

For example, the first wavelength L1 may be 20 μm and 30 μm, and the first amplitude W1 may be between 5 μm and 10 μm. For example, the first wavelength L1 may be also between 35 μm and 45 μm, and the first amplitude W1 may be between 8 μm and 14 μm. For another example, the first wavelength L1 may be also between 50 μm and 60 μm, and the first amplitude W1 may be between 12 μm and 20 μm.

The second wall surface 31B is formed to extend in the second direction Y in the plan view, and curves in a wavy line shape toward one side (the outside of the opening 30) in the first direction X and the other side (the inside of the opening 30) in the first direction X. More specifically, the second wall surface 31B, in the plan view, includes at least one (multiple in this embodiment) second recess portion 34 recessed in an arc toward one side in the first direction X, and at least one (multiple in this embodiment) second protrusion portion 35 protruding in an arc toward the other side in the first direction X. The second protrusion portion 35 and the second recess portion 34 are adjacent in the second direction Y. More specifically, multiple second protrusion portions 35 and multiple second recess portions 34 are formed alternately in the second direction Y.

When a second imaginary line YL connecting one end and the other end of the second wall surface 31B in the second direction Y is set, the multiple second recess portions 34 recess toward one side in the first direction X with respect to the second imaginary line YL and the multiple second protrusion portions 35 protrude toward the other side in the first direction X with respect to the second imaginary line YL. A protrusion width of the second protrusion portion 35 in the first direction X by using the second imaginary line YL as a reference is preferably substantially equal to a recess width of the second recess portion 34 in the first direction X by using the second imaginary line YL as a reference.

Thus, the second wall surface 31B in the plan view forms as a wavy line shape that depicts a second sinusoidal curve SC2. That is, the multiple second recess portions 34 respectively form multiple valleys of the second sinusoidal curve SC2, and the multiple second protrusion portions 35 respectively form multiple hills of the second sinusoidal curve SC2.

In this embodiment, one end and the other end of the second wall surface 31B are formed by the second recess portions 34 (that is, the valleys of the second sinusoidal curve SC2). One end and the other end of the second wall surface 31B are preferably set as zero points (starting points of the recess of the second recess portion 34) of the second sinusoidal curve SC2.

The second recess portion 34 of one end of the second wall surface 31B is connected to the first recess portion 32 of one end of the first wall surface 31A. That is, the opening corner of the opening 30 is obtained by defining the first recess portion 32 recessed toward the second direction Y and the second recess portion 34 recessed toward the first direction X. Accordingly, the contact (poor layout) of the first protrusion portion 33 and the second protrusion portion 35 at the opening corner is inhibited.

In this embodiment, the second wall surface 31B has a constant second wavelength L2 in the plan view. The second wavelength L2 is defined by a distance of a portion of the second wall surface 31B in the second direction Y, wherein the portion includes the second recess portion 34 and the second protrusion portion 35 adjacent to each other. The second wavelength L2 may also be defined by a distance between the centers of two adjacent second recess portions 34 in the second direction Y, or a distance between the centers of two adjacent second protrusion portions 35 in the second direction Y.

The second wavelength L2 may be between 5 μm and 100 μm. The second wavelength L2 may also be between 5 μm and 25 μm, between 25 μm and 50 μm, between μm and 75 μm, or between 75 μm and 100 μm. The second wavelength L2 is preferably between 20 μm and 60 μm.

In this embodiment, the second wall surface 31B has a constant second amplitude W2 in the plan view. The second amplitude W2 may be defined by a distance between the center of the second recess portion 34 and the center of the second protrusion portion 35 in the first direction X. The second amplitude W2 is also a sum of the protrusion width and the recess width.

The second amplitude W2 may be between 1 μm and 50 μm. The second amplitude W2 may also be between 1 μm and 10 μm, between 10 μm and 20 μm, between μm and 30 μm, between 30 μm and 40 μm, or between 40 μm and 50 μm. The second amplitude W2 is preferably between 5 μm and 25 μm.

For example, the second wavelength L2 may be between 20 μm and 30 μm, and the second amplitude W2 may be between 5 μm and 10 μm. For example, the second wavelength L2 may also be between 35 μm and 45 μm, and the second amplitude W2 may be between 8 μm and 14 μm. For another example, the second wavelength L2 may also be between 50 μm and 60 μm, and the second amplitude W2 may be between 12 μm and 20 μm.

The second wavelength L2 may be greater than the first wavelength L1 or be less than the first wavelength L1. The second wavelength L2 is preferably substantially equal to the first wavelength L1. The second amplitude W2 may be greater than the first amplitude W1 or be less than the first amplitude W1. The second amplitude W2 is preferably substantially equal to the first amplitude W1.

The second wall surface 31B may include one or more second protrusion portions 35 having a protrusion width greater than the protrusion width of the first protrusion portions 33. The second wall surface 31B may also include one or more second protrusion portions 35 having a protrusion width less than the protrusion width of the first protrusion portions 33. The second wall surface 31B may further include one or more second protrusion portions 35 having a protrusion width substantially equal to the protrusion width of the first protrusion portions 33.

The second wall surface 31B may include one or more second recess portions 34 having a recess width greater than the recess width of the first recess portions 32. The second wall surface 31B may also include one or more second recess portions 34 having a recess width less than the recess width of the first recess portions 32. The second wall surface 31B may further include one or more second recess portions 34 having a recess width substantially equal to the recess width of the first recess portions 32.

The third wall surface 31C, similar to the first wall surface 31A, includes the first recess portions 32 and the first protrusion portions 33. The number of the first recess portions 32 of the third wall surface 31C is equal to the number of the first recess portions 32 of the first wall surface 31A. Moreover, the number of the first protrusion portions 33 of the third wall surface 31C is equal to the number of the first protrusion portions 33 of the first wall surface 31A.

The multiple first recess portions 32 of the third wall surface 31C are respectively opposite to the multiple first recess portions 32 of the first wall surface 31A in one-to-one correspondence in the second direction Y. Moreover, the multiple first protrusion portions 33 of the third wall surface 31C are respectively opposite to the multiple first protrusion portions 33 of the first wall surface 31A in one-to-one correspondence in the second direction Y. The first recess portion 32 of one end of the third wall surface 31C is connected to the second recess portion 34 of the other end of the second wall surface 31B.

However, the layout (the number, the first wavelength L1 and the first amplitude W1) of the first recess portions 32 and the first protrusion portions 33 of the third wall surface 31C may also be different from the layout of the first recess portions 32 and the first protrusion portions 33 of the first wall surface 31A. For example, the first recess portions 32 of the third wall surface 31C may also be opposite to at least one first protrusion portion 33 of the first wall surface 31A in the second direction Y. For example, the first protrusion portion 33 of the third wall surface 31C may also be opposite to at least one first recess portion 32 of the first wall surface 31A in the second direction Y.

Apart from the above, the structure of the third wall surface 31C is the same as the structure of the first wall surface 31A. The remaining details of the third wall surface 31C may be acquired by replacing “the first wall surface 31A” in the description associated with the first wall surface 31A by “the third wall surface 31C”.

The fourth wall surface 31D, similar to the second wall surface 31B, includes the second recess portions 34 and the second protrusion portions 35. The number of the second recess portions 34 of the fourth wall surface 31D is equal to the number of the second recess portions 34 of the second wall surface 31B. Moreover, the number of the second protrusion portions 35 of the fourth wall surface 31D is equal to the number of the second protrusion portions 35 of the second wall surface 31B.

The multiple second recess portions 34 of the fourth wall surface 31D are respectively opposite to the multiple second recess portions 34 of the second wall surface 31B in one-to-one correspondence in the second direction Y. Moreover, the multiple second protrusion portions 35 of the fourth wall surface 31D are respectively opposite to the multiple second protrusion portions 35 of the second wall surface 31B in one-to-one correspondence in the second direction Y. The second recess portion 34 of one end of the fourth wall surface 31D is connected to the first recess portion 32 of the other end of the first wall surface 31A. The second recess portion 34 of the other end of the fourth wall surface 31D is connected to the first recess portion 32 of the other end of the third wall surface 31C.

However, the layout (the number, the second wavelength L2 and the second amplitude W2) of the second recess portions 34 and the second protrusion portions 35 of the fourth wall surface 31D may also be different from the layout of the second recess portions 34 and the second protrusion portions 35 of the second wall surface 31B. For example, the second recess portions 34 of the fourth wall surface 31D may also be opposite to at least one second protrusion portion 35 of the second wall surface 31B in the first direction X. For example, the second protrusion portions 35 of the fourth wall surface 31D may also be opposite to at least one second recess portion 34 of the second wall surface 31B in the first direction X.

Apart from the above, the structure of the fourth wall surface 31D is the same as the structure of the second wall surface 31B. The remaining details of the fourth wall surface 31D may be acquired by replacing “the second wall surface 31B” in the description associated with the second wall surface 31B by “the fourth wall surface 31D”.

In this embodiment, the electronic device 1A includes, in the second inorganic film 22, a thickness gradually decreasing portion 36 formed around the opening 30. The thickness gradually decreasing portion 36 may be regarded as a constituent of the second inorganic film 22. The thickness gradually decreasing portion 36 is disposed in a portion located around the opening 30 and where the film thickness of the second inorganic film 22 gradually decreases toward the opening 30.

In this embodiment, the thickness gradually decreasing portion 36 is formed in a portion of the second inorganic film 22 covering the fourth color filter film 15D, and has a thickness less than the thickness of a portion covering the region other than the fourth color filter film 15D (for example, the portion covering the first to third color filter films 15A to 15C).

The thickness gradually decreasing portion 36 extends as a strip along the wall surface 31 of the opening 30 in the plan view. More specifically, the thickness gradually decreasing portion 36 extends as a ring along the first to fourth wall surfaces 31A to 31D of the opening 30. In this embodiment, the thickness gradually decreasing portion 36 defines the first to fourth wall surfaces 31A to 31D. That is, the first to fourth wall surfaces 31A to 31D are obtained by defining a portion having a relatively small thickness in the second inorganic film 22.

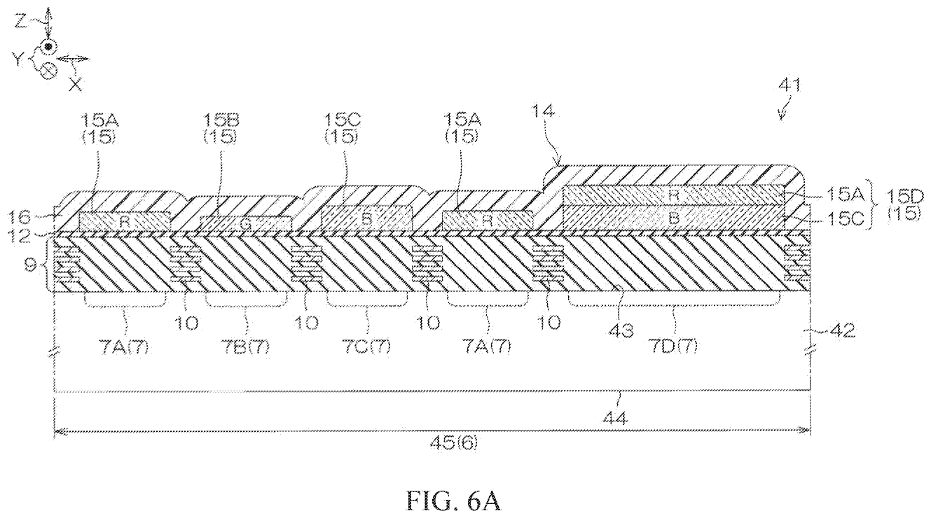

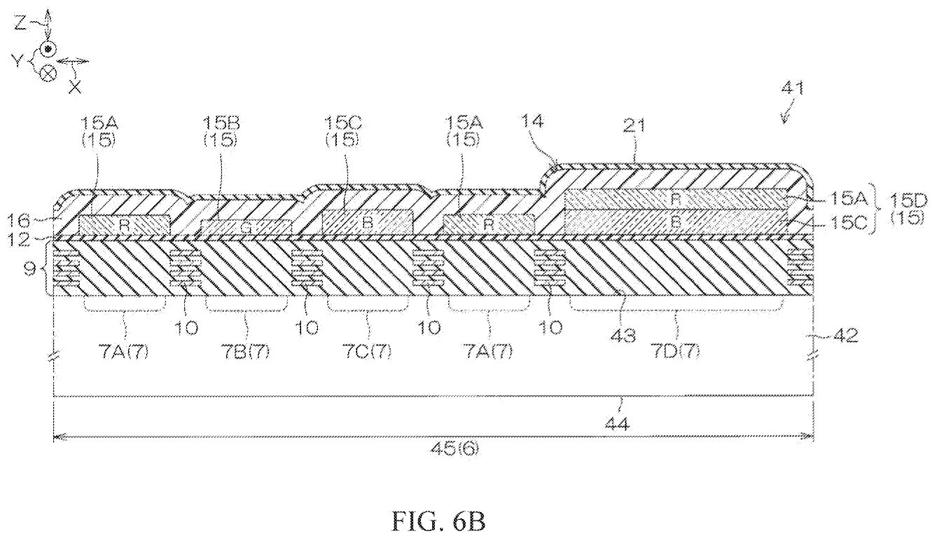

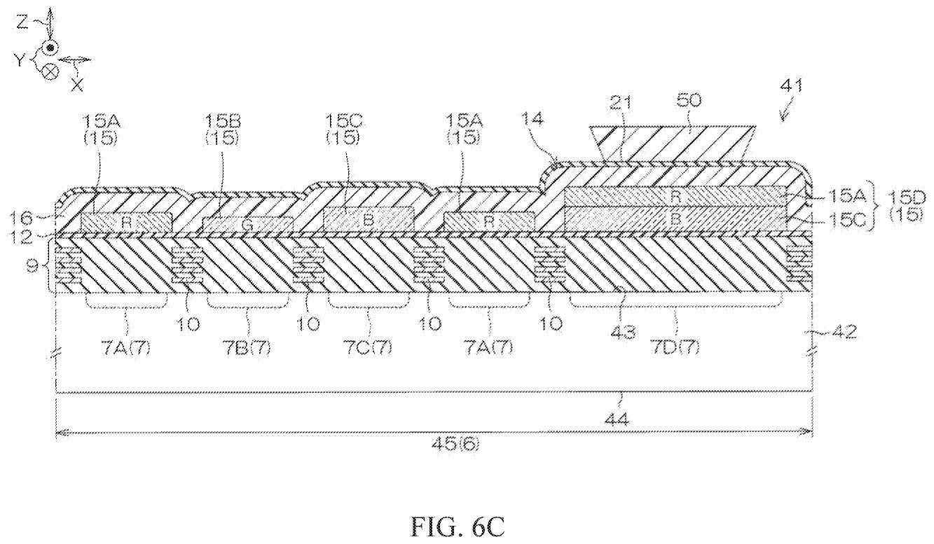

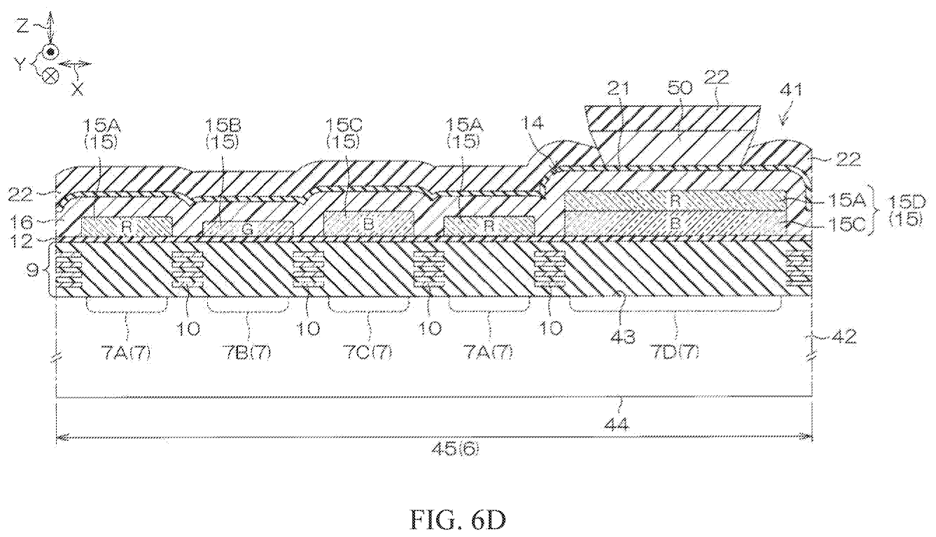

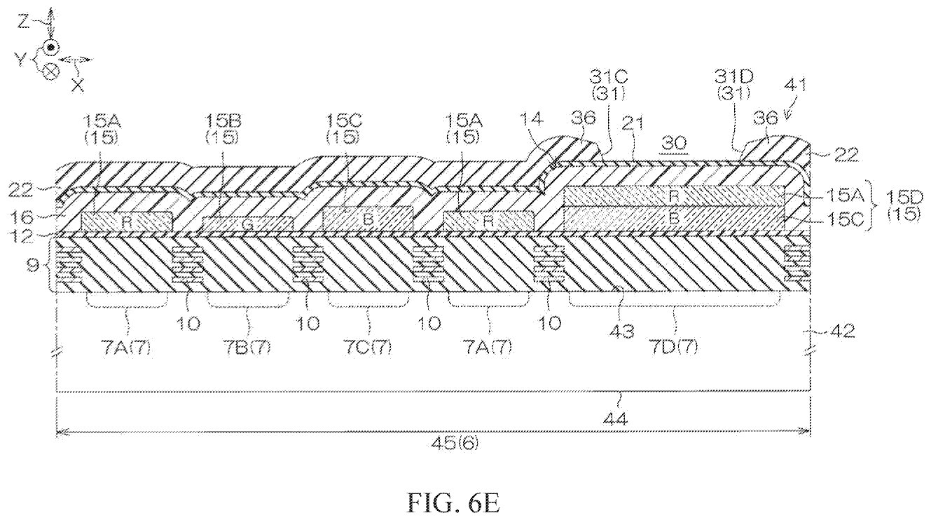

FIG. 6A to FIG. 6E are sectional views of a part of a method of manufacturing the electronic device 1A shown in FIG. 1. Referring to FIG. 6A, a wafer structure 41 is first prepared. The wafer structure 41 includes a wafer 42 to become the substrate of the chip 2. The wafer 42 includes a first wafer main surface 43 on one side and a second wafer main surface 44 on the other side. The first wafer main surface 43 and the second wafer main surface 44 respectively correspond to the first main surface 3 and the second main surface 4 of the chip 2.

The wafer structure 41 includes multiple device regions 45 set at the wafer 42. The multiple device regions 45 are regions respectively corresponding to electronic devices 1A. The multiple device regions 45 may be set to arrange at intervals in the first direction X and the second direction Y to appear as an array in the plan view.

The wafer structure 41 includes a light receiving region 6, a circuit region 8, an interlayer insulating film 9, multiple wirings 10 (multi-layer wirings), a base inorganic insulating film 12 and multiple organic films 14 in the device regions 45. FIG. 6A to FIG. 6E show the structure of the light receiving region 6 in one device region 45. The light receiving region 6 includes multiple light receiving devices 7 (first to fourth light receiving devices 7A to 7D) formed on the first wafer main surface 43. The circuit region 8 includes a logic circuit formed on the first wafer main surface 43.

The interlayer insulating film 9 covers the multiple device regions 45 all at once on the first wafer main surface 43. The multiple wirings 10 are formed in portions of the interlayer insulating film 9 covering the device regions 45, respectively. The base inorganic insulating film 12 covers the multiple device regions 45 all at once in the plan view. The multiple organic films 14 are formed in portions of the base inorganic insulating film 12 covering the multiple device regions 45, respectively. Each organic film 14 includes multiple color filter films 15 (first to fourth color filter films 15A to 15D) and a transparent filter film 16 in each device region 45.

Next, referring to FIG. 6B, a first inorganic film 21 covering the multiple organic films 14 is formed on the base inorganic insulating film 12. The first inorganic film 21 may be formed by means of sputtering. After the first inorganic film 21 is formed, the first inorganic film 21 may be formed to have a desired layout by means of etching implemented through a mask having a predetermined layout. The first inorganic film 21 may also be formed by means of chemical vapor deposition (CVD).

Then, referring to FIG. 6C, a resist film 50 having a predetermined layout is formed on a covering target of the first inorganic film 21. The resist film 50 is formed by a photoresist film (that is, a negative or positive photosensitive resin film). The resist film may include at least one of a polyimide film, a polyamide film, a polybenzoxazole film and an acrylic film.

The resist film 50 is formed to have the predetermined layout by a step of coating with a photosensitive resin, a step of exposing the photosensitive resin, and a step of developing the photosensitive resin. The resist film 50 covers a region expected to form an opening 30, and exposes a region other than that. In this embodiment, the resist film 50 covers a portion of the first inorganic film 21 covering the fourth color filter film and exposes a region other than that portion.

Next, referring to FIG. 6D, a second inorganic film 22 covering the first inorganic film 21 and the resist film 50 is formed. The second inorganic film 22 has a thickness less than the thickness of the resist film 50, and is formed to partially expose the resist film 50. In this embodiment, the step of forming the second inorganic film 22 includes alternately forming multiple silicon oxide films and multiple titanium oxide films. The silicon oxide films and titanium oxide films may be respectively formed by means of sputtering. However, the second inorganic film 22 may be formed by means of CVD.

Then, referring to FIG. 6E, the resist film 50 is removed. In this step, the portion in the second inorganic film 22 covering the resist film 50 is together removed along with the resist film 50. Accordingly, the opening 30 formed by the removed portion of the resist film 50 is defined in the second inorganic film 22. Then, the wafer structure 41 is cut along the multiple device regions 45 to thereby manufacture multiple electronic devices 1A.

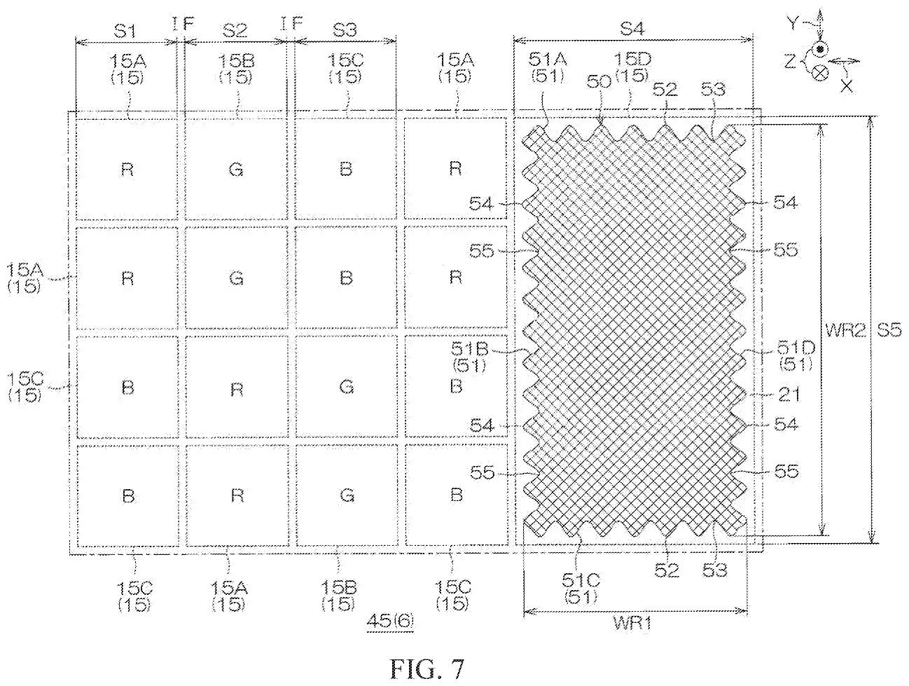

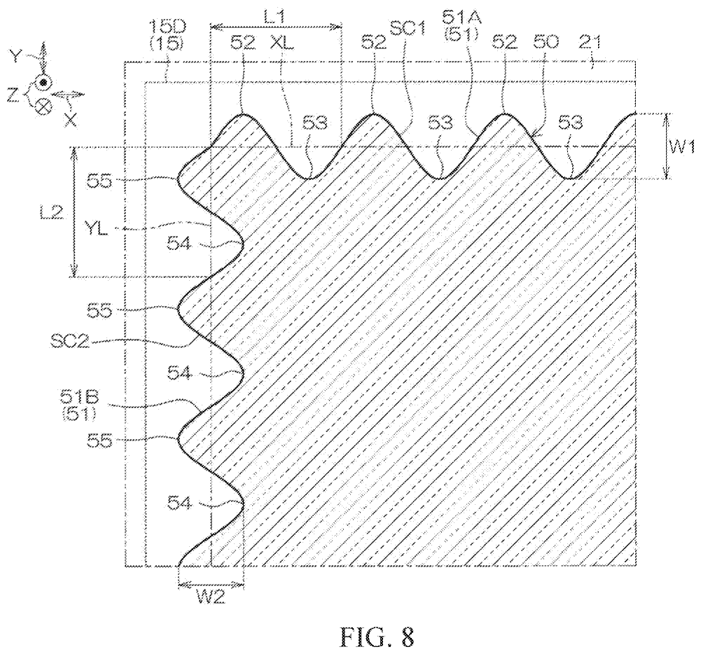

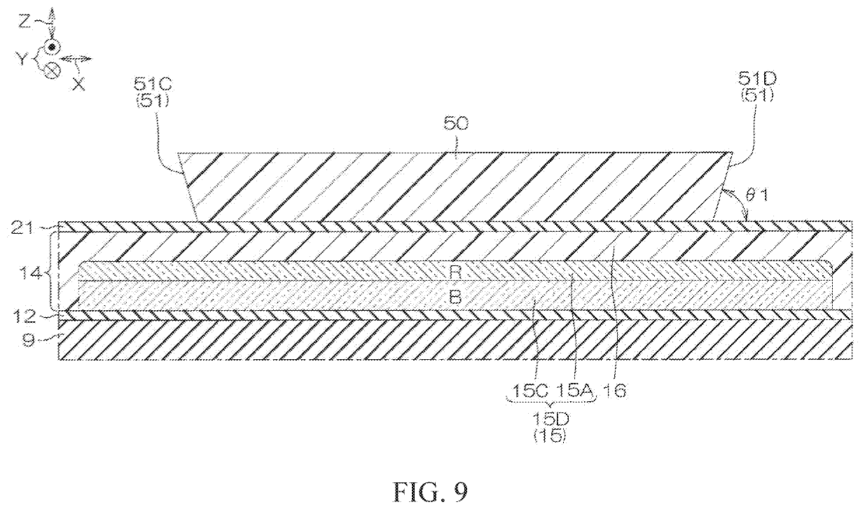

FIG. 7 shows an enlarged plan view of the layout of the resist film 50 shown in FIG. 6C. FIG. 8 shows an enlarged plan view of a main portion of the resist film 50 shown in FIG. 7. FIG. 9 shows an enlarged sectional view of the resist film 50 shown in FIG. 7.

Referring to FIG. 7 to FIG. 9, in the step of forming the resist film 50, the resist film 50 having a layout corresponding to the opening 30 is formed. That is, in this embodiment, the resist film 50 covers a region surrounded by the periphery of the fourth color filter film 15D at a distance inwardly from the periphery of the fourth color filter film 15D in the plan view.

In this embodiment, the resist film 50 is shaped as a quadrilateral (specifically a rectangle extending in the second direction Y) in the plan view. The resist film 50 has a first resist width WR1 in the first direction X and a second resist width WR2 in the second direction Y. The first resist width WR1 is substantially equal to the first opening width WO1. The second resist width WR2 is substantially equal to the second opening width WO2.

A resist area of the resist film 50 is substantially equal to the opening area of the opening 30. That is, the resist area is preferably greater than the pad opening area of each pad opening 13. Moreover, the resist area is preferably greater than the planar areas of the first to third color filter films 15A to 15C, and less than the planar area of the fourth filter film 15D.

The resist film 50 includes a resist sidewall 51 extending along the periphery of the fourth color filter film 15D. In this embodiment, the resist sidewall 51 includes first to fourth resist sidewalls 51A to 51D. The first resist sidewall 51A extends in the first direction X in the plan view, and forms a short side of the resist film 50. The first resist sidewall 51A has an end on one side in the first direction X and the other end on the other side in the first direction X.

The second resist sidewall 51B extends from one end of the first resist sidewall 51A in the second direction Y in the plan view, and forms a long side of the resist film 50. The second resist sidewall 51B has an end on one side in the second direction Y and the other end on the other side in the second direction Y. One end of the second resist sidewall 51B and one end of the first resist sidewall 51A form one resist corner.

The third resist sidewall 51C extends from the other end of the second resist sidewall 51B in the first direction X in the plan view, and forms the short side of the resist film 50. The third resist sidewall 51C is opposite to the first resist sidewall 51A in the second direction Y. The third resist sidewall 51C has an end on one side in the first direction X and the other end on the other side in the first direction X. One end of the third resist sidewall 51C and the other end of the second resist sidewall 51B form one resist corner.

The fourth resist sidewall 51D extends in a region between the other end of the first resist sidewall 51A and the other end of the third resist sidewall 51C in the second direction Y in the plan view, and forms the long side of the resist film 50. The fourth resist sidewall 51D is opposite to the second resist sidewall 51B in the first direction X. The fourth resist sidewall 51D has an end on one side in the second direction Y and the other end on the other side in the second direction Y. One end of the fourth resist sidewall 51D and the other end of the first resist sidewall 51A form one resist corner, and the other end of the fourth resist sidewall 51D and the other end of the third resist sidewall 51C form one resist corner.

Referring to FIG. 7 and FIG. 8, the resist film 50 has a portion curved in a wavy line shape in at least one of the first to fourth resist sidewalls 51A to 51D. In this embodiment, the resist film 50 has a portion curved in a wavy line shape in all of the first to fourth resist sidewalls 51A to 51D. That is, the resist sidewall 51 entirely and globally curves in a wavy line shape in the plan view. The structure of the first resist sidewall 51A and the structure of the second resist sidewall 51B are to be specifically described below.

The first resist sidewall 51A is formed to extend in the first direction X in the plan view, and curves in a wavy line shape toward one side (the outside of the resist film in the second direction Y and the other side (the inside of the resist film 50) in the second direction Y. More specifically, the first resist sidewall 51A, in the plan view, includes at least one (multiple in this embodiment) first resist protrusion portion 52 protruding in an arc toward one side in the second direction Y, and at least one (multiple in this embodiment) first resist recess portion 53 recessed in an arc toward the other side in the second direction Y.

The first resist recess portion 53 and the first resist protrusion portion 52 are adjacent in the second direction Y. More specifically, multiple first resist recess portions 53 and multiple first resist protrusion portions 52 are formed alternately in the first direction X. When a first imaginary line XL connecting one end and the other end of the first resist sidewall 51A in the first direction X is set, the multiple first resist protrusion portions 52 protrude toward one side in the second direction Y with respect to the first imaginary line XL and the multiple first resist recess portions 53 recess toward the other side in the second direction Y with respect to the first imaginary line XL.

A recess width of the first resist recess portion 53 in the second direction Y by using the first imaginary line XL as a reference is preferably substantially equal to a protrusion width of the first resist protrusion portion 52 in the second direction Y by using the first imaginary line XL as a reference. The protrusion width of the first resist protrusion portion 52 is equivalent to the recess width of the first recess portion 32 of the opening 30, and the recess width of the first resist recess portion 53 is equivalent to the protrusion width of the first protrusion portion 33 of the opening 30.

Thus, the first resist sidewall 51A in the plan view forms as a wavy line shape that depicts a first sinusoidal curve SC1. That is, the multiple first resist protrusion portions 52 respectively form multiple hills of the first sinusoidal curve SC1, and the multiple first resist recess portions 53 respectively form multiple valleys of the first sinusoidal curve SC1.

In this embodiment, one end and the other end of the first resist sidewall 51A are respectively formed by the first resist protrusion portions 52 (that is, the hills of the first sinusoidal curve SC1). One end and the other end of the first resist sidewall 51A are preferably set as zero points (starting points of the protrusion of the first resist protrusion portion 52) of the first sinusoidal curve SC1.

In this embodiment, the first resist sidewall 51A has a constant first wavelength L1 in the plan view. The first wavelength L1 is defined by a distance of a portion of the first resist sidewall 51A in the first direction X, wherein the portion includes the first resist protrusion portion 52 and the first resist recess portion 53 adjacent to each other. The first wavelength L1 may also be defined by a distance between the centers of two adjacent first resist protrusion portions 52 in the first direction X, or a distance between the centers of two adjacent first resist recess portions 53 in the first direction X. The first wavelength L1 of the resist film 50 is equivalent to the first wavelength L1 of the opening 30.

The first resist sidewall 51A has a constant first amplitude W1 in the plan view. The first amplitude W1 may be defined by a distance between the center of the first resist protrusion portion 52 and the center of the first resist recess portion 53 in the second direction Y. The first amplitude W1 of the resist film 50 is equivalent to the first amplitude W1 of the opening 30.

The second resist sidewall 51B is formed to extend in the second direction Y in the plan view, and curves in a wavy line shape toward one side (the outside of the resist film 50) in the first direction X and the other side (the inside of the resist film 50) in the first direction X. More specifically, the second resist sidewall 51B, in the plan view, includes at least one (multiple in this embodiment) second resist protrusion portion 54 protruding in an arc toward one side in the first direction X, and at least one (multiple in this embodiment) second resist recess portion 55 recessed in an arc toward the other side in the first direction X.

The second resist recess portion 55 and the second resist protrusion portion 54 are adjacent in the second direction Y. More specifically, multiple second resist recess portions 55 and multiple second resist protrusion portions 54 are formed alternately in the second direction Y. When a second imaginary line YL connecting one end and the other end of the second resist sidewall 51B in the second direction Y is set, the multiple second resist protrusion portions 54 protrude toward one side in the first direction X with respect to the second imaginary line YL and the multiple second resist recess portions 55 recess toward the other side in the first direction X with respect to the second imaginary line YL.

A recess width of the second resist recess portion 55 in the first direction X by using the second imaginary line YL as a reference is preferably substantially equal to a protrusion width of the second resist protrusion portion 54 in the first direction X by using the second imaginary line YL as a reference. The protrusion width of the second resist protrusion portion 54 is equivalent to the recess width of the second recess portion 34 of the opening 30, and the recess width of the second resist recess portion 55 is equivalent to the protrusion width of the second protrusion portion 35 of the opening 30.

Thus, the second resist sidewall 51B in the plan view forms as a wavy line shape that depicts a second sinusoidal curve SC2. That is, the multiple second resist protrusion portions 54 respectively form multiple hills of the second sinusoidal curve SC2, and the multiple second resist recess portions 55 respectively form multiple valleys of the second sinusoidal curve SC2.

In this embodiment, one end and the other end of the second resist sidewall 51B are formed by the second resist protrusion portions 54 (that is, the hills of the second sinusoidal curve SC2). One end and the other end of the second resist sidewall 51B are preferably set as zero points (starting points of the protrusion of the second resist protrusion portion 54) of the second sinusoidal curve SC2.

The second resist protrusion portion 54 of one end of the second resist sidewall 51B is connected to the first resist protrusion portion 52 of one end of the first resist sidewall 51A. That is, the resist corner is obtained by defining the first resist protrusion portion 52 protruding toward the second direction Y and the second resist protrusion portion 54 protruding toward the first direction X. Accordingly, the communication (poor layout) of the first resist recess portion 53 and the second resist recess portion 55 at the resist corner is inhibited.

The second resist sidewall 51B has a constant second wavelength L2 in the plan view. The second wavelength L2 is defined by a distance of a portion of the second resist sidewall 51B in the second direction Y, wherein the portion includes the second resist protrusion portion 54 and the second resist recess portion 55 adjacent to each other. The second wavelength L2 may also be defined by a distance between the centers of two adjacent second resist protrusion portions 54 in the second direction Y, or a distance between the centers of two adjacent second resist recess portions 55 in the second direction Y. The second wavelength L2 of the resist film 50 is equivalent to the second wavelength L2 of the opening 30.

The second resist sidewall 51B has a constant second amplitude W2 in the plan view. The second amplitude W2 may be defined by a distance between the center of the second resist protrusion portion 54 and the center of the second resist recess portion 55 in the first direction X. The second amplitude W2 of the resist film 50 is equivalent to the second amplitude W2 of the opening 30.

The third resist sidewall 51C, similar to the first resist sidewall 51A, includes the first resist protrusion portions 52 and the first resist recess portions 53. The number of the first resist protrusion portions 52 of the third resist sidewall 51C is equal to the number of the first resist protrusion portions 52 of the first resist sidewall 51A. Moreover, the number of the first resist recess portions 53 of the third resist sidewall 51C is equal to the number of the first resist recess portions 53 of the first resist sidewall 51A.

The multiple first resist protrusion portions 52 of the third resist sidewall 51C are respectively opposite to the multiple first resist protrusion portions 52 of the first resist sidewall 51A in one-to-one correspondence in the second direction Y. Moreover, the multiple first resist recess portions 53 of the third resist sidewall 51C are respectively opposite to the multiple first resist recess portions 53 of the first resist sidewall 51A in one-to-one correspondence in the second direction Y. The first resist protrusion portion 52 of one end of the third resist sidewall 51C is connected to the second resist protrusion portion 54 of the other end of the second resist sidewall 51B.

However, the layout (the number, the first wavelength L1 and the first amplitude W1) of the first resist protrusion portions 52 and the first resist recess portions 53 of the third resist sidewall 51C may also be different from the layout of the first resist protrusion portions 52 and the first resist recess portions 53 of the first resist sidewall 51A.

For example, the first resist protrusion portions 52 of the third resist sidewall 51C may also be opposite to at least one first resist recess portion 53 of the first resist sidewall 51A in the second direction Y. For example, the first resist recess portions 53 of the third resist sidewall 51C may also be opposite to at least one first resist protrusion portion 52 of the first resist sidewall 51A in the second direction Y.

Apart from the above, the structure of the third resist sidewall 51C is the same as the structure of the first resist sidewall 51A. The remaining details of the third resist sidewall 51C may be acquired by replacing “the first resist sidewall 51A” in the description associated with the first resist sidewall 51A by “the third resist sidewall 51C”.

The fourth resist sidewall 51D, similar to the second resist sidewall 51B, includes the second resist protrusion portions 54 and the second resist recess portions 55. The number of the second resist protrusion portions 54 of the fourth resist sidewall 51D is equal to the number of the second resist protrusion portions 54 of the second resist sidewall 51B. Moreover, the number of the second resist recess portions 55 of the fourth resist sidewall 51D is equal to the number of the second resist recess portions 55 of the second resist sidewall 51B.

The multiple second resist protrusion portions 54 of the fourth resist sidewall 51D are respectively opposite to the multiple second resist protrusion portions 54 of the second resist sidewall 51B in one-to-one correspondence in the second direction Y. Moreover, the multiple second resist recess portions 55 of the fourth resist sidewall 51D are respectively opposite to the multiple second resist recess portions 55 of the second resist sidewall 51B in one-to-one correspondence in the second direction Y.

The second resist protrusion portion 54 of one end of the fourth resist sidewall 51D is connected to the first resist protrusion portion 52 of the other end of the first resist sidewall 51A. The second resist protrusion portion 54 of the other end of the fourth resist sidewall 51D is connected to the first resist protrusion portion 52 of the other end of the third resist sidewall 51C.

However, the layout (the number, the second wavelength L2 and the second amplitude W2) of the second resist protrusion portions 54 and the second resist recess portions 55 of the fourth resist sidewall 51D may also be different from the layout of the second resist protrusion portions 54 and the second resist recess portions 55 of the second resist sidewall 51B.

For example, the second resist protrusion portions 54 of the fourth resist sidewall 51D may also be opposite to at least one second resist protrusion portion 54 of the second resist sidewall 51B in the first direction X. For example, the second resist recess portions 55 of the fourth resist sidewall 51D may also be opposite to at least one second resist protrusion portion 54 of the second resist sidewall 51B in the first direction X.

In addition, the structure of the fourth resist sidewall 51D is the same as the structure of the second resist sidewall 51B. The remaining details of the fourth resist sidewall 51D may be acquired by replacing “the second resist sidewall 51B” in the description associated with the second resist sidewall 51B by “the fourth resist sidewall 51D”.

Referring to FIG. 9, each of the first to fourth resist sidewalls 51A to 51D may also be formed as an inverted tapered shape forming an acute angle with an outer surface of the first inorganic film 21 in the plan view. In this case, the first to fourth resist sidewalls 51A to 51D are opposite to the first inorganic film 21 at an interval in a lamination direction (normal direction Z). In the sectional view, the form in which the first to fourth resist sidewalls 51A to 51D curve in an arc shape (for example, an arc) toward the outside of the resist film 50 is also included in the expression “inverted tapered shape” herein.

An inclination angle θ1 of the first to fourth resist sidewalls 51A to 51D relative to the outer surface of the first inorganic film 21 may be between 45° and 90°. The inclination angle θ1 of the first to fourth resist sidewalls 51A to 51D is an angle formed between a straight line connecting upper ends and lower ends of the first to fourth resist sidewalls 51A to 51D and the outer surface of the first inorganic film 21.

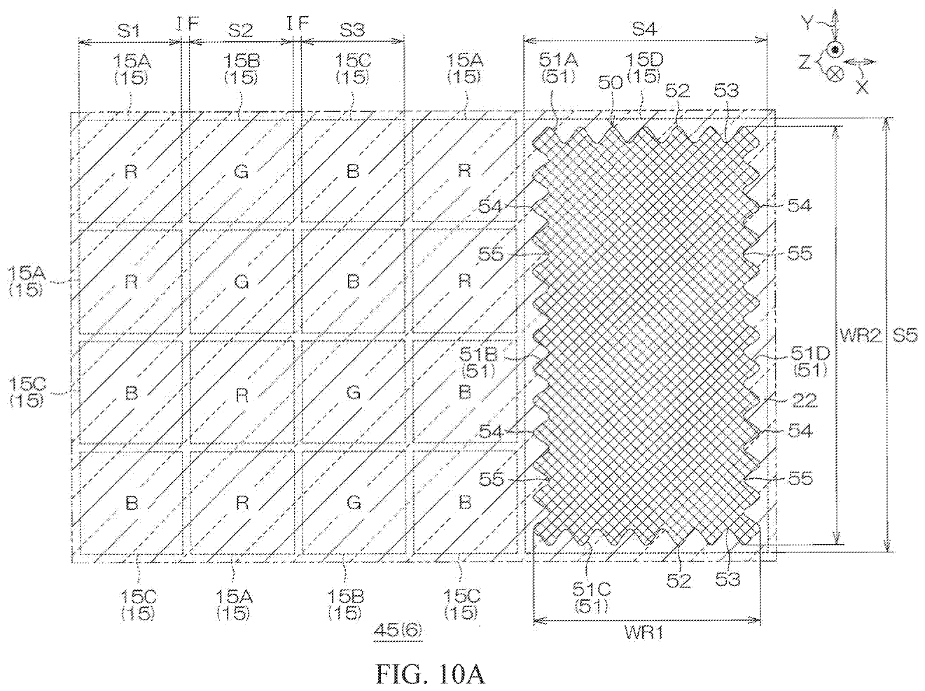

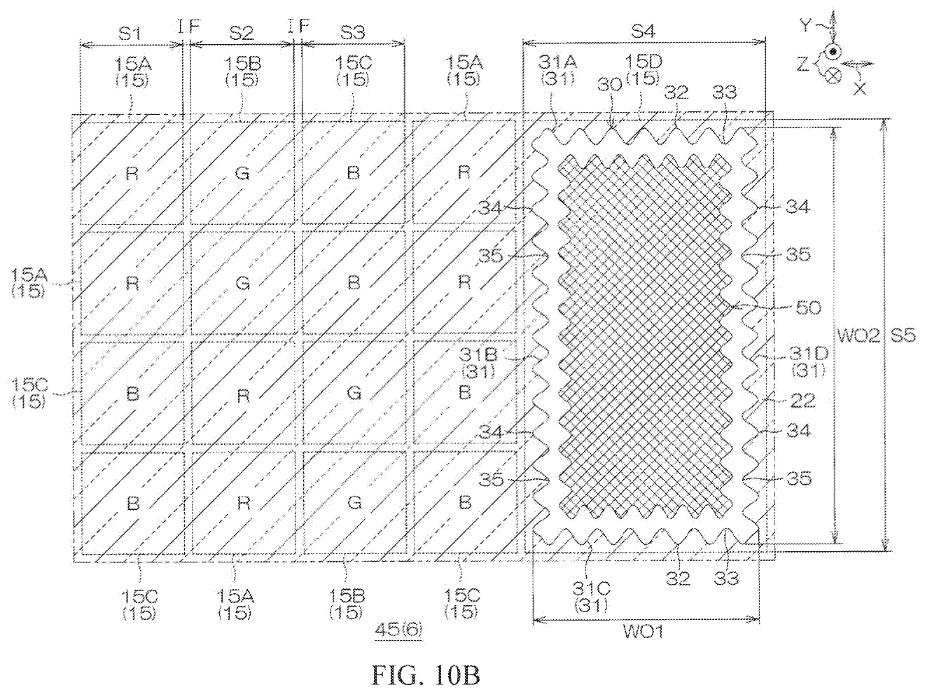

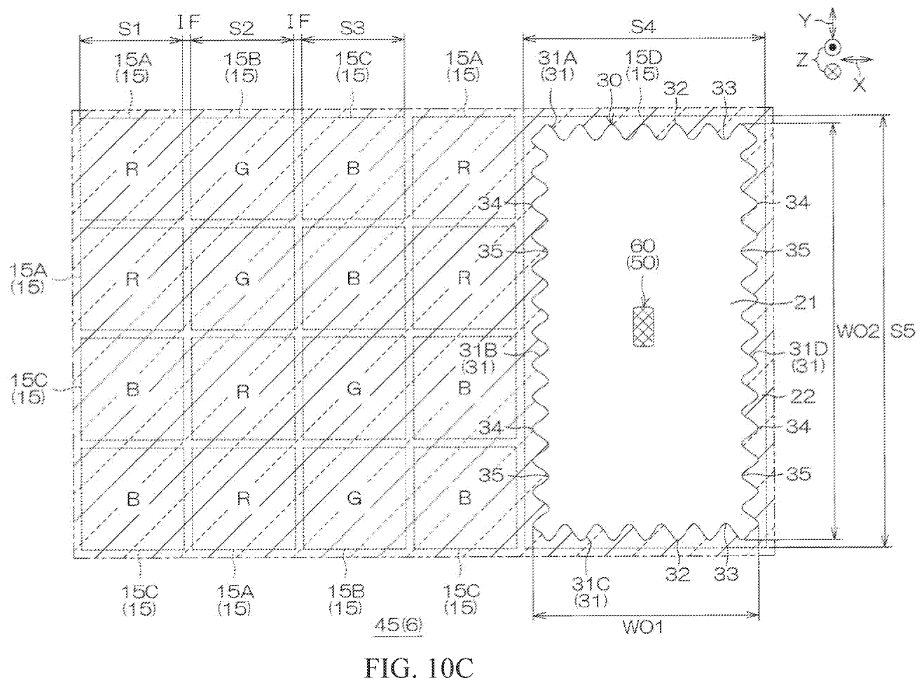

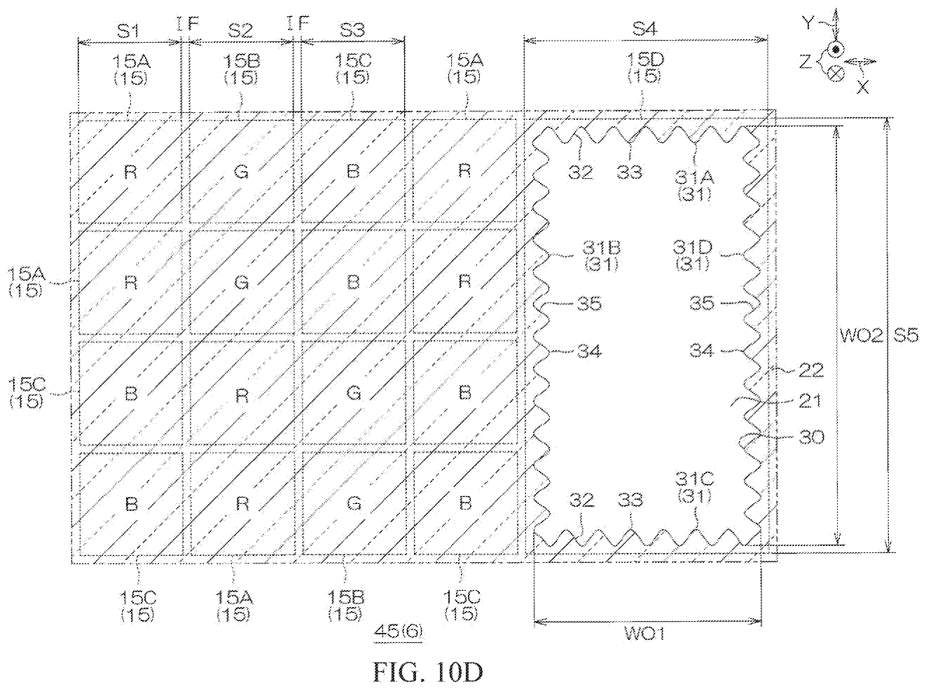

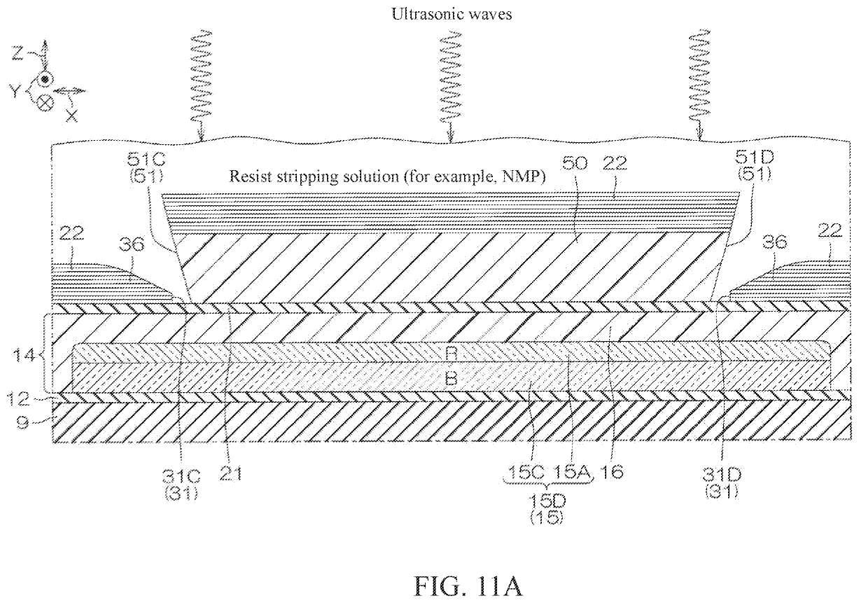

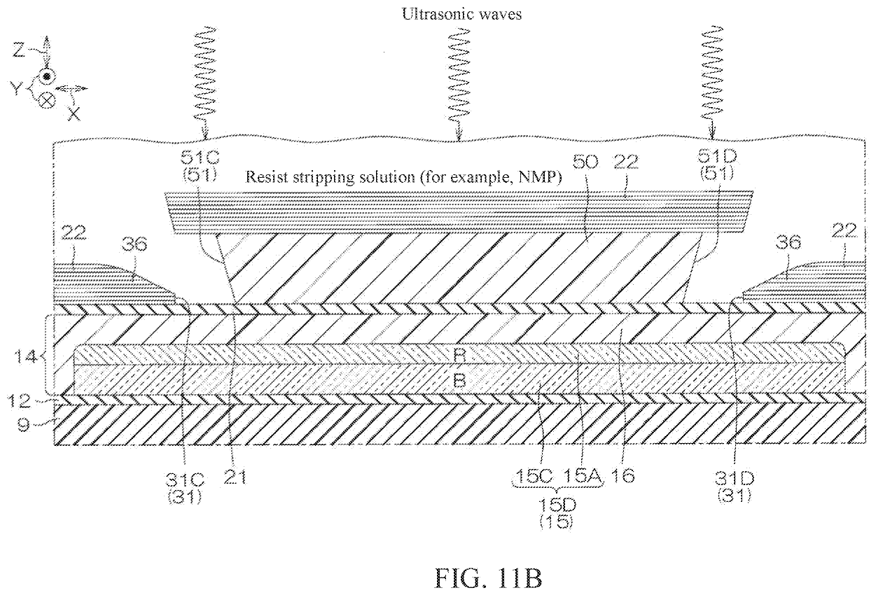

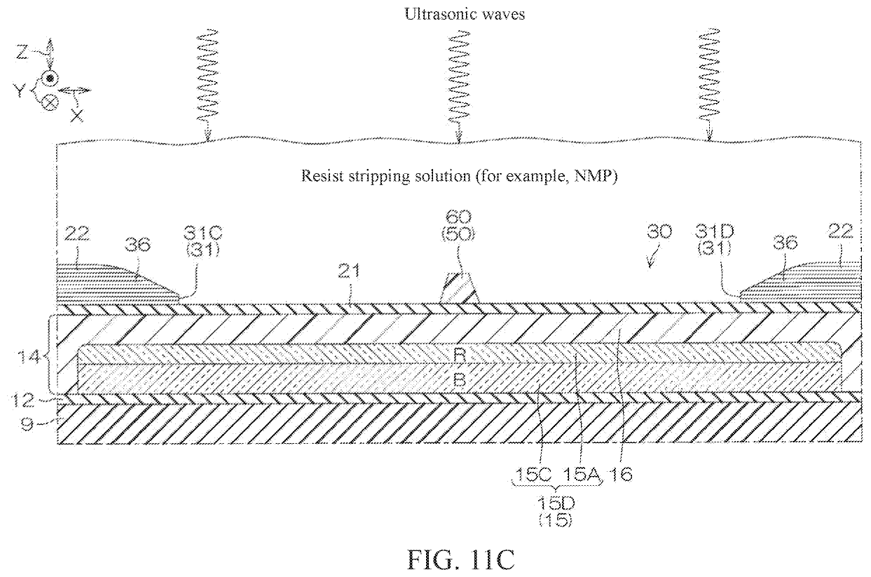

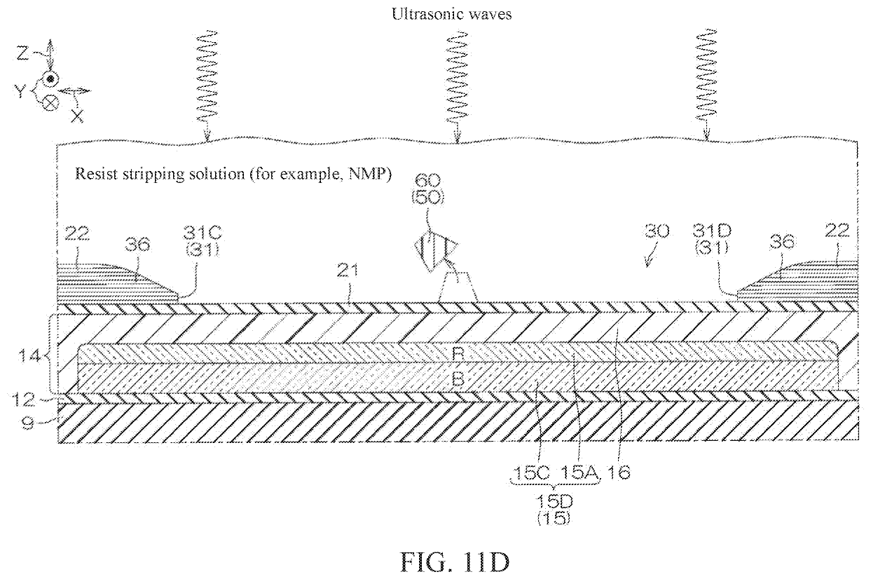

FIG. 10A to FIG. 10D are enlarged plan views for specifically illustrating steps of forming the opening 30. FIG. 11A to FIG. 11D are enlarged sectional views for specifically illustrating steps of forming the opening 30. FIG. 10A to FIG. 10D and FIG. 11A to FIG. 11D show steps of forming the opening 30 according to a time sequence.

Referring to FIG. 10A and FIG. 11A, in the step of forming the second inorganic film 22 (referring to FIG. 6D), the second inorganic film 22 is formed on the first inorganic film 21 to cover the resist film 50 having the layout (referring to FIG. 7 and FIG. 8). The second inorganic film 22 has a thickness less than the thickness of the resist film 50, and covers the first inorganic film 21 and the resist film 50 to expose a portion or all of the first to fourth resist sidewalls 51A to 51D of the resist film 50.

A portion in the second inorganic film 22, apart from the region covering the resist film 50, covers the first inorganic film 21 to curve in a wavy line shape along the first to fourth resist sidewalls 51A to 51D. Accordingly, the opening 30 having the first to fourth wall surfaces 31A to 31D that curve in wavy line shapes along the first to fourth resist sidewalls 51A to 51D is defined.

That is, the multiple first recess portions 32 of the opening 30 are formed along the multiple first resist protrusion portions 52 of the resist film 50, and the multiple first protrusion portions 33 of the opening 30 are formed along the multiple first resist recess portions 53 of the resist film 50. Moreover, the multiple second recess portions 34 of the opening 30 are formed along the second resist protrusion portions 54 of the resist film 50, and the multiple second protrusion portions 35 of the opening 30 are formed along the multiple second resist recess portions 55 of the resist film 50.

After the step of forming the second inorganic film 22, a step of removing the resist film 50 (referring to FIG. 6E) is implemented. In the step of removing the resist film 50, a stripping bath filled with a resist stripping solution (chemical solution) for removing the resist film 50 is used. The resist stripping solution may be, for example, a resist stripping solution containing N-methyl-2-pyrrolidone (NMP). In consideration of environmental impact, an NMP-free organic solvent-based resist stripping solution can also be used.

The wafer structure 41 is placed in the stripping bath to at least immerse the resist film 50 and the second inorganic film 22 in the resist stripping solution. However, the wafer structure 41 may be entirely immersed in the resist stripping solution. Further, in this step, in order to facilitate stripping of the resist film 50, ultrasonic waves are applied to the resist film 50. For example, ultrasonic waves are applied to the resist film 50 from an ultrasonic vibrator arranged in the stripping bath via the wafer structure 41 and the resist stripping solution.

Referring to FIG. 10B and FIG. 11B, after the resist film 50 is immersed in the resist stripping solution, the resist film 50 gradually dissolves toward the inside from the first to fourth resist sidewalls 51A to 51D exposed between the first inorganic film 21 and the second inorganic film 22. Accordingly, the first to fourth wall surfaces 31A to 31D of the opening 30 become exposed to form a structure in which a residual portion of the resist film 50 is arranged in the opening 30. The infiltration rate of the resist stripping solution into the resist film 50 is increased by ultrasonic vibration.

Referring to FIG. 10C and FIG. 11C, once the resist film 50 scales down to a certain size (a release size of the second inorganic film 22), the second inorganic film 22 is released from the resist film 50. Accordingly, a resist residual portion 60 formed by a single structure of the residual portion of the resist film 50 is formed on the first inorganic film 21 in the opening 30. Ultrasonic vibration is continuously applied to the resist residual portion 60.

Referring to FIG. 10D and FIG. 11D, the resist residual portion 60, after being totally dissolved by the resist stripping solution on the first inorganic film 21 or being physically stripped off from the first inorganic film 21 by ultrasonic vibration, dissolves in the resist stripping solution. With such time-lapse process, the opening 30 formed by the removed portion of the resist film 50 is formed in the second inorganic film 22.

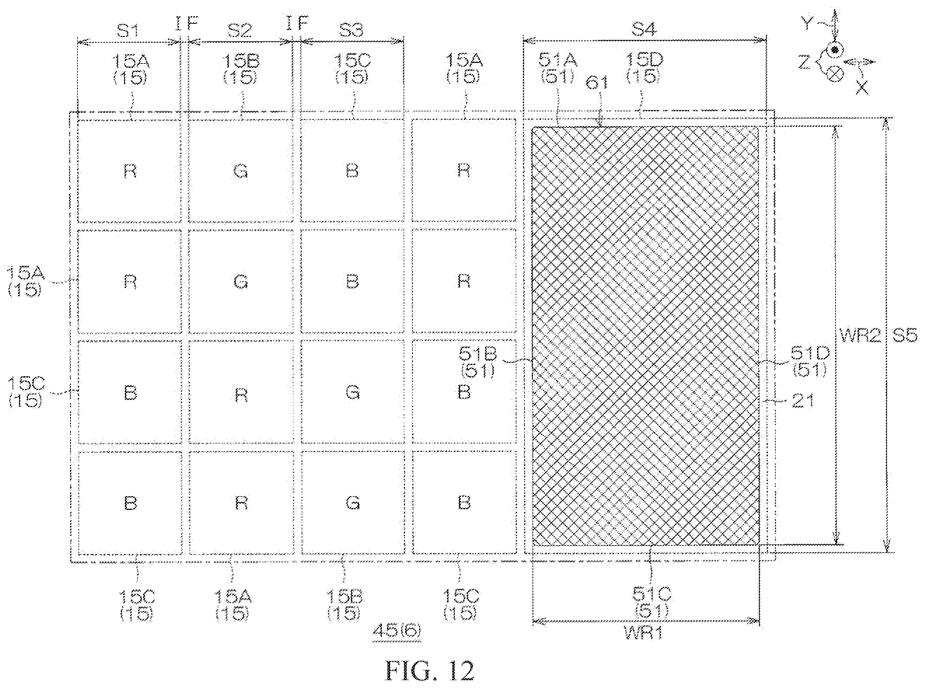

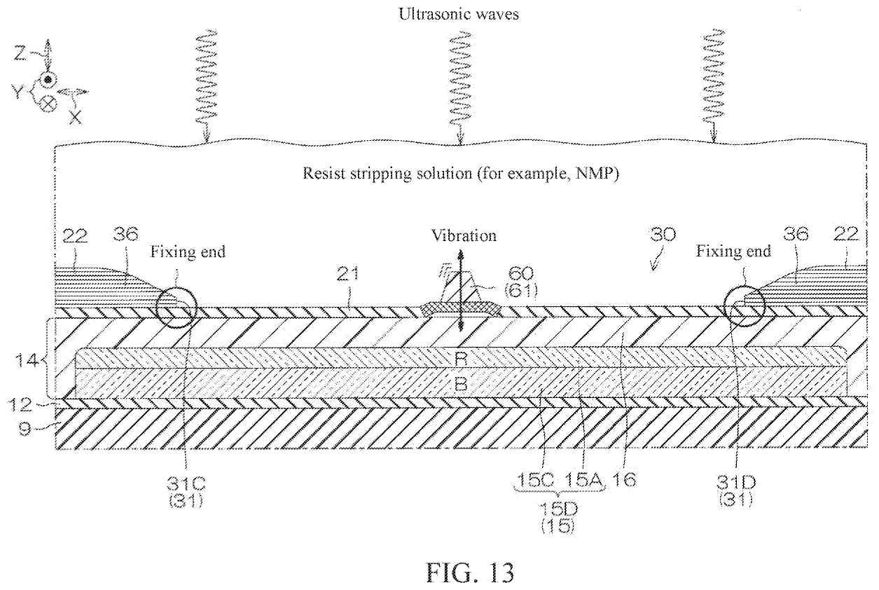

FIG. 12 shows an enlarged plan view of a reference resist film 61. FIG. 13 shows an enlarged cross-sectional view of a manufacturing step using the reference resist film 61. Referring to FIG. 12, apart from including the first to fourth resist sidewalls 51A to 51D extending as straight lines in the plan view, details of the structure of the reference resist film 61 are the same as the structure of the resist film 50.

Refer to FIG. 13, in a step of removing the reference resist film 61, after the time-lapse process the same as that in FIG. 10A to FIG. 10D (FIG. 11A to FIG. 11D), an opening 30 having first to fourth wall surfaces 31A to 31D extending as straight lines is formed in a second inorganic film 22, and a resist residual portion 60 is formed on a first inorganic film 21 in the opening 30. Ultrasonic vibration is continuously applied to the resist residual portion 60.

A portion of the first inorganic film 21 exposed (exposed portion) from the opening 30 vibrates in an up-down direction due to the ultrasonic vibration serving as an external force. At this point in time, the first to fourth wall surfaces 31A to 31D extending as straight lines respectively function as fixing ends for the exposed portion of the first inorganic film 21, such that the vibrational amplitude of the exposed portion of the first inorganic film 21 is increased. As a result, the exposed portion of the first inorganic film 21 is damaged by such as cracks. More particularly, in the manufacturing steps, during a period in which the exposed portion of the first inorganic film 21 vibrates together with the resist residual portion 60 in an up-down direction, the damage of the exposed portion of the first inorganic film 21 is inclined to occur at a portion that supports the resist residual portion 60.

In this structure, the opening 30 is defined in the second inorganic film 22 that is thicker than the first inorganic film 21 and less likely to deform than the first inorganic film 21. That is, the function of the second inorganic film 22 serving as the fixing end for the exposed portion of the first inorganic film 21 is improved with the above structure of the second inorganic film 22.

Accordingly, a location right below the exposed portion of the first inorganic film 21 becomes an organic film 14. The organic film 14 has a modulus of elasticity less than the modulus of elasticity of the first inorganic film 21 and the modulus of elasticity of the second inorganic film 22. Thus, the organic film 14 is easily deformed due to ultrasonic vibration, and is also easily deformed due to vibration of the first inorganic film 21. That is to say, the organic film 14 tolerates deformation of the first inorganic film 21, hence forming a structure in which the exposed portion of the first inorganic film 21 is sandwiched by the organic film 14 and the second inorganic film 22 to vibrate in an up-down direction.

With the structure above, when the exposed portion of the first inorganic film 21 vibrates in an up-down direction, problems such as stripping of the first inorganic film 21 or cracks of the first inorganic film 21 may occur on the organic film 14. In the event that the first inorganic film 21 is stripped, a gap is formed between the organic film 14 and the first inorganic film 21, and the refractive index of incident light changes due to the gap. In the event that cracks occur in the first inorganic film 21, the refractive index of incident light changes owing to the cracks. These problems can be a type of criteria for visible appearance defects that can be observed through the appearance.

In view of the above, in the method of manufacturing the electronic device 1A, in the step of forming the resist film 50, the resist film 50 having a resist sidewall 51 curved in a wavy line shape in the plan view is formed to partially cover the first inorganic film 21. In the step of forming the second inorganic film 22, the second inorganic film 22 covering the first inorganic film 21 and the resist film 50 is formed to expose at least a portion of the resist sidewall 51. Then, in the step of removing the resist film 50, the resist film 50 is removed, and the opening 30 having the wall surface 31 curving as a wavy line shape in the plan view is formed in the second inorganic film 22 to partially expose the first inorganic film 21.

According to the manufacturing method, the phase of vibration of the fixing end can be dispersed by the wall surface 31 curved in a wavy line shape of the opening 30. Accordingly, an increase in the vibrational amplitude of the first inorganic film 21 caused by vibration of the fixing end can be inhibited. As a result, damage such as cracks of the first inorganic film 21 can be inhibited. Accordingly, the electronic device 1A with improved reliability can be manufactured and provided.

The step of removing of the resist film 50 includes immersing the resist film 50 in a resist stripping solution. According to the manufacturing method, an increase in the vibrational amplitude of the first inorganic film 21 in the resist stripping solution can be further inhibited, while the resist film 50 dissolves in the resist stripping solution.

The step of removing the resist film 50 may also include a step of applying ultrasonic waves to the resist film 50. According to the manufacturing method, the resist film 50 can be removed by ultrasonic waves. Moreover, an increase in the vibrational amplitude of the fixing end of the first inorganic film 21 caused by ultrasonic waves can be inhibited. Accordingly, damage such as cracks of the first inorganic film 21 caused by ultrasonic waves can be inhibited. The step of removing of the resist film 50 preferably includes a step of applying ultrasonic waves and removing the resist film 50 by a resist stripping solution at the same time. In this case, the time for stripping the resist film 50 can be reduced, and the resist film 50 can be appropriately removed at the same time.

The method of manufacturing the electronic device 1A may also include a step of forming the first inorganic film 21 on the organic film 14. According to the manufacturing method, on the organic film 14, an increase in the vibrational amplitude of the first inorganic film 21 caused by vibration of the fixing end can be inhibited. Thus, on the organic film 14, damage such as stripping or cracks of the first inorganic film 21 can be inhibited. For a structure in which the organic film 14 is irradiated by light, in the first inorganic film 21, changes in the refractive index caused by stripping or cracks can be inhibited, and thus the organic film 14 can be appropriately irradiated by light through the first inorganic film 21.

On the other hand, the electronic device 1A includes a first inorganic film 21, a second inorganic film 22 and an opening 30. The second inorganic film 22 covers the first inorganic film 21. The opening 30 is formed in the second inorganic film 22 to partially expose the first inorganic film 21, and has a wall surface 31 curved in a wavy line shape in the plan view. According to the structure, the phase of vibration of the fixing end can be dispersed by the wall surface 31 curved in a wavy line shape of the opening 30.

Accordingly, an increase in the vibrational amplitude of the first inorganic film 21 caused by vibration of the fixing end can be inhibited. As a result, damage such as cracks of the first inorganic film 21 can be inhibited. Accordingly, the electronic device 1A with improved reliability can be provided. Examples of external forces applied to the electronic device 1A may be from vibration during an operation process, vibration of applications mounted in the electronic device 1A and ultrasonic vibration applied on the electronic device 1A from a soldering needle during connection of bonding wires.

The electronic device 1A may also include an organic film 14. In this case, the first inorganic film 21 may directly cover the organic film 14. According to the structure above, on the organic film 14, an increase in the vibrational amplitude of the first inorganic film 21 caused by vibration of the fixing end can be inhibited. Thus, on the organic film 14, damage such as stripping or cracks of the first inorganic film 21 can be inhibited. The first inorganic film 21 can be thinner than the organic film 14.

The electronic device 1A may further include a chip 2, light receiving devices 7 (functional devices) formed on the chip 2, and an interlayer insulating film 9 covering the light receiving devices 7. In this case, the organic film 14 may cover the interlayer insulating film 9. According to the structure above, the light receiving devices 7 can be appropriately irradiated by light through the organic film 14 and the first inorganic film 21.

The organic film 14 may include a transparent filter film 16 (transparent resin film). In this structure, the first inorganic film 21 may cover the transparent filter film 16. According to the structure above, the transparent filter film 16 can be appropriately irradiated by light through the first inorganic film 21.

The organic film 14 may also include at least one color filter film 15. In this case, the transparent filter film 16 may cover the color filter film 15. Moreover, in this case, the opening 30 may expose a portion of the first inorganic film 21 covering the color filter film 15. According to the structure above, the color filter film 15 can be appropriately irradiated by light through the first inorganic film 21 and the transparent filter film 16.

The wall surface 31 of the opening 30 preferably has a first wall surface 31A extending in the first direction X in the plan view and a second wall surface 31B extending in the second direction Y in the plan view. In this case, the first wall surface 31A, in the plan view, preferably has a first recess portion 32 recessed toward one side in the second direction Y, and a first protrusion portion 33 protruding toward the other side in the second direction Y.

Moreover, the second wall surface 31B, in the plan view, preferably has a second recess portion 34 recessed toward one side in the first direction X, and a second protrusion portion 35 protruding toward the other side in the first direction X. According to the structure above, an increase in the vibrational amplitude of the first inorganic film 21 caused by vibration of the fixing end can be inhibited by the first wall surface 31A and the second wall surface 31B respectively curved in wavy line shapes both in the first direction X and the second direction Y.

The first wall surface 31A preferably has an end formed by the first recess portion 32. Moreover, the second wall surface 31B preferably has an end formed by the second recess portion 34 and connected to the end of the first wall surface 31A. According to the structure above, the contact between the first protrusion portion 33 of the first wall surface 31A and the second protrusion portion 35 of the second wall surface 31B at a corner of the opening 30 can be inhibited. Accordingly, the opening 30 can be formed with an appropriate layout.

The wall surface 31 of the opening 30 may have a constant wavelength in the plan view. The wall surface 31 of the opening 30 may also have a constant amplitude in the plan view. The second inorganic film 22 is preferably thicker than the first inorganic film 21. According to the structure above, the first inorganic film 21 can be appropriately protected by the second inorganic film 22. The second inorganic film 22 may have a thickness between 1 μm and 15 μm.

The second inorganic film 22 includes a thickness gradually decreasing portion 36 disposed around the opening 30 and having a film thickness gradually decreased toward the opening 30. According to the structure above, the function of using the wall surface 31 of the opening 30 as a fixing end can be weakened.

The second inorganic film 22 has a laminated structure including multiple inorganic films. In this case, the second inorganic film 22 may have a laminated structure including a silicon oxide film and a titanium oxide film. Further, in these cases, the second inorganic film 22 may be formed as an optical filter film. In this case, the opening may be formed as a light extraction opening formed on the optical filter film. According to the structures above, changes in the refractive index caused by cracks can be inhibited by a portion of the first inorganic film 21 exposed from the optical filter film.

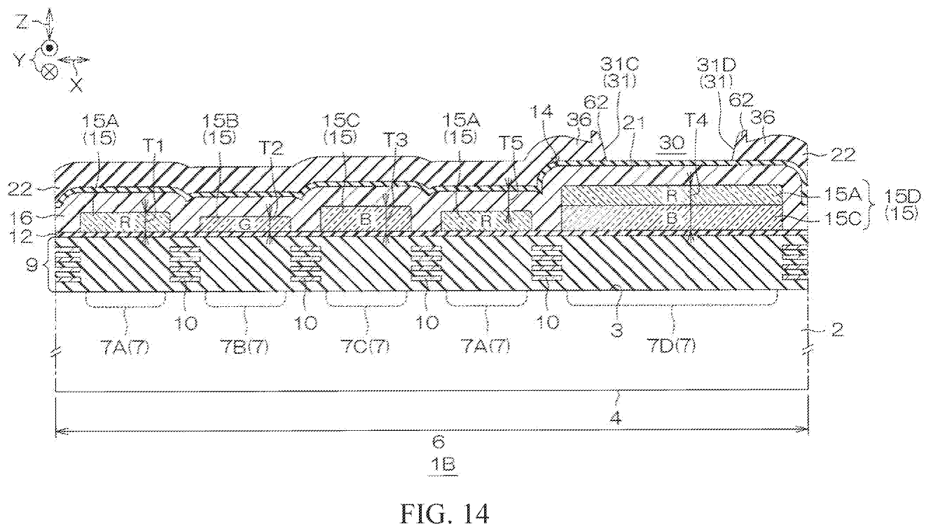

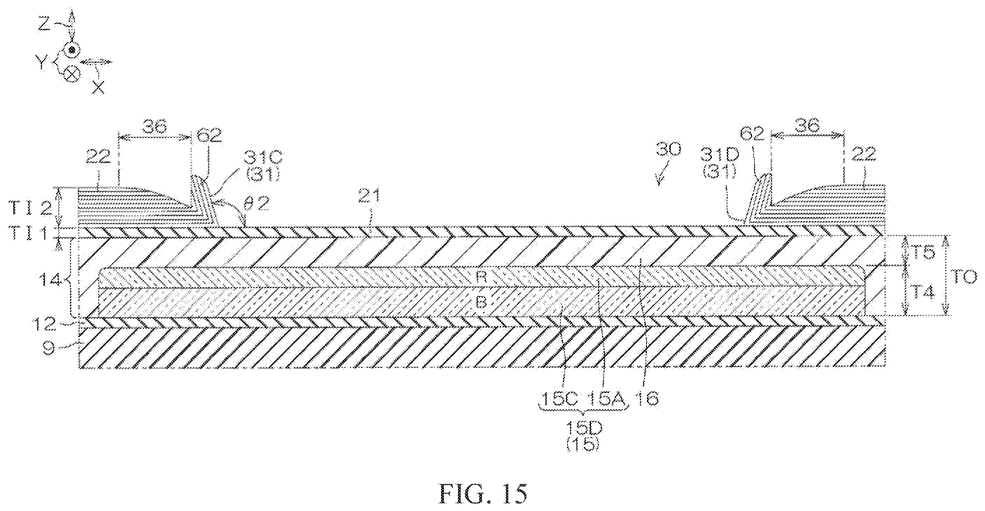

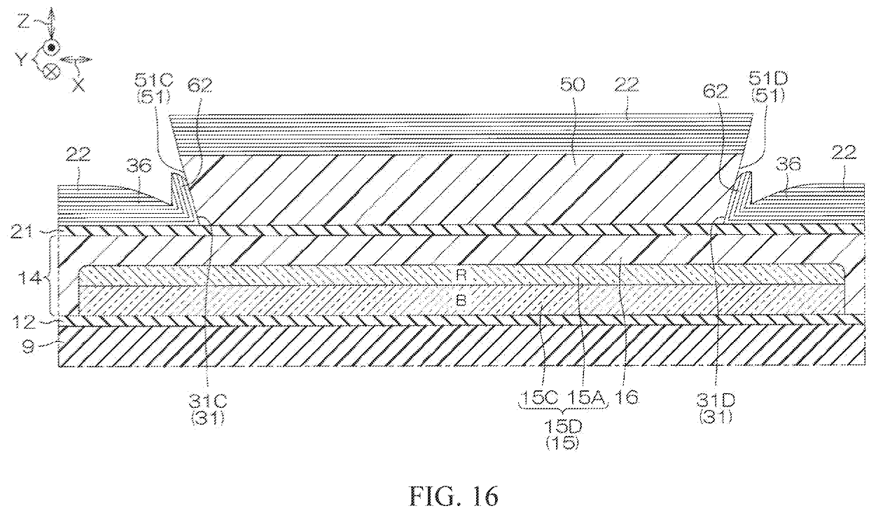

FIG. 14 shows a sectional view of an electronic device 1B of a second embodiment. FIG. 15 shows an enlarged sectional view of a region including the opening shown in FIG. 14. FIG. 16 shows an enlarged sectional view of a step of forming the second inorganic film 22 shown in FIG. 14.

Referring to FIG. 14 and FIG. 15, the electronic device 1B, in a portion defining the wall surface 31 of the opening 30 in the second inorganic film 22, includes a protruding portion 62 that protrudes toward an opposite side of the first inorganic film 21. In this embodiment, the protruding portion 62 defines at least a portion of the wall surface 31 of the opening 30 curved in a wavy line shape. The protruding portion 62 may be regarded as a constituent of the second inorganic film 22 and/or the opening 30.

The protruding portion 62 may be formed as an inverted tapered shape forming an obtuse angle with an outer surface of the first inorganic film 21 in the sectional view. In the sectional view, the form in which the protruding portion 62 curves in an arc shape (for example, an arc) toward the outside of the opening 30 is also included in the expression “inverted tapered shape” herein. An inclination angle θ2 of the protruding portion 62 with respect to the outer surface of the first inorganic film 21 may be between and 135°. The inclination angle θ2 of the protruding portion 62 is an angle formed between a straight line connecting an upper end and the lower end of the protruding portion 62 and the outer surface of the first inorganic film 21.

The protruding portion 62 extends as a strip along the wall surface 31 of the opening 30 in the plan view. In this embodiment, the protruding portion 62 extends in a ring along the full periphery (that is, the first to fourth wall surfaces 31A to 31D) of the wall surface 31 in the plan view. That is, in this embodiment, the protruding portion 62 defines the first to fourth wall surfaces 31A to 31D curved in wavy line shapes. The protruding portion 62 may have an amount of protrusion greater than the thickness of the center of the thickness gradually decreasing portion 36 in the normal direction Z. The amount of protrusion of the protruding portion 62 may also be greater than the thickness of the second inorganic film 22. The width of the protruding portion 62 is preferably less than the width of the thickness gradually decreasing portion 36.

In this embodiment, the protruding portion 62 has a laminated structure obtained by a silicon oxide film and a titanium oxide film laminated in the horizontal direction (first direction X/second direction Y) and extending as films in the vertical direction (normal direction Z). In this embodiment, the protruding portion 62 has a multi-layer laminated structure obtained by alternately laminating multiple silicon oxide films and multiple titanium oxide films. The multiple silicon oxide films and the multiple titanium oxide films of the protruding portion 62 are continually extended from a portion of the multiple silicon oxide films and a portion of the multiple titanium oxide films of the second inorganic film 22.

Referring to FIG. 16, the protruding portion 62 is formed by the following operations; that is, in the step of forming the second inorganic film 22 (referring to FIG. 6D), a portion apart from the region in the second inorganic film 22 (the multiple silicon oxide films and the multiple titanium oxide films) forming the resist film 50 is formed and connected to the first to fourth resist sidewalls 51A to 51D.

As described above, the method of manufacturing the electronic device 1B can also provide the same effects as the effects of the method of manufacturing the electronic device 1A. Moreover, the electronic device 1B can also provide the same effects as the electronic device 1A.

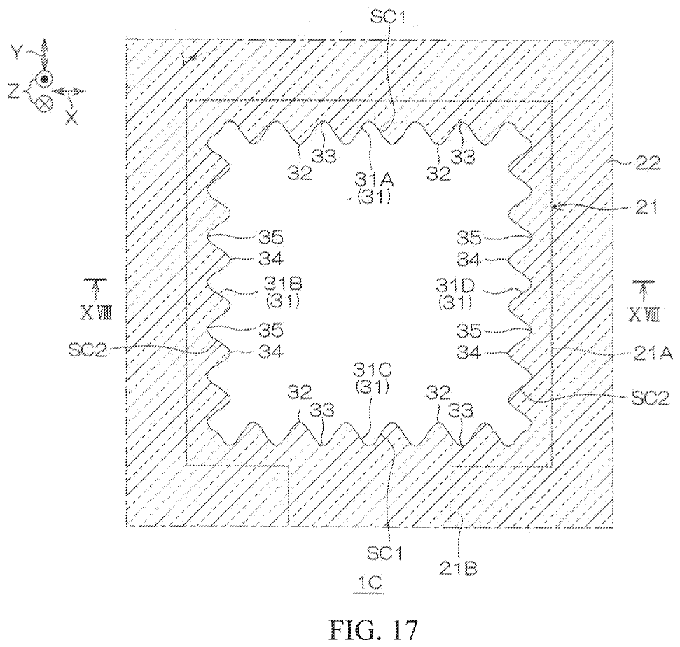

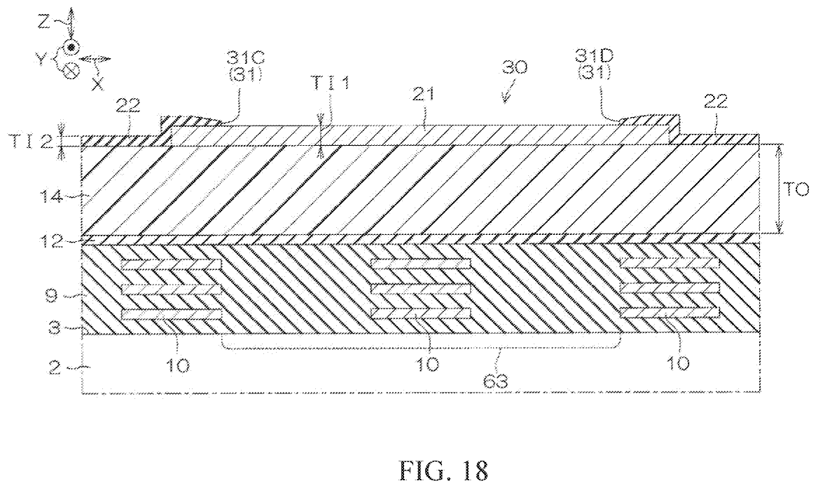

FIG. 17 shows an enlarged plan view of a main portion of an electronic device 1C of a third embodiment. FIG. 18 shows a sectional view along the line XVIII-XVIII in FIG. 17. The electronic device 1C is formed by a device (a semiconductor apparatus, for example) other than an illuminance sensor (semiconductor light receiving apparatus). Similar to the electronic device 1A, the electronic device 1C includes a chip 2, an interlayer insulating film 9, multiple wirings 10 (multi-layer wirings), a base inorganic insulating film 12, an organic film 14, a first inorganic film 21, a second inorganic film 22, an opening 30 and a thickness gradually decreasing portion 36.

The electronic device 1C includes a functional device 63 formed on the first main surface 3 of the chip 2. The functional device 63 is depicted in a simplified form by a dotted line in FIG. 18. The functional device 63 is formed by means of using a surface layer portion of the first main surface 3 or a region on the first main surface 3. The functional device 63 may also include at least one of a semiconductor switching device, a semiconductor rectifying device and a passive device. The functional device 63 may also be an integrated circuit formed by a combination of at least two of a semiconductor switching device, a semiconductor rectifying device and a passive device.

The semiconductor switching device may include at least one of a metal insulator semiconductor field effect transistor (MISFET), a complementary MISFET, a bipolar junction transistor (BJT), an insulated gate bipolar junction transistor (IGBT), and a junction field effect transistor (JFET).

The semiconductor rectifying device may include at least one of a pn junction diode, a pin junction diode, a Zener diode, a Schottky barrier diode, and a fast recovery diode. The passive device may include at least one of a resistor, a capacitor, an inductor and a fuse.

The interlayer insulating film 9 covers the functional device 63 on the first main surface 3. The multiple wirings 10 are arranged in the interlayer insulating film 9 to be electrically connected to the functional device 63. The multiple wirings 10 may also be arranged on the interlayer insulating film 9, specifically depending on the specifications of the functional device 63. In this case, the multiple wirings 10 may pass through the interlayer insulating film 9 so as to be electrically connected to the functional device 63. In this case, the multiple wirings 10 are electrically connected to the functional device 63 through multiple via electrodes embedded in the interlayer insulating film 9, for example.

The base inorganic insulating film 12 covers the interlayer insulating film 9. When the multiple wirings 10 are arranged on the interlayer insulating film 9, the base inorganic insulating film 12 covers the multiple wirings 10 on the interlayer insulating film 9 to partially expose the multiple wirings 10.

The organic film 14 covers the base inorganic insulating film 12. When the multiple wirings 10 are arranged on the interlayer insulating film 9, the organic film 14 covers the base inorganic insulating film 12 to partially expose the multiple wirings 10. In this embodiment, the organic film 14 has a single-layer structure formed by a transparent resin film.

The organic film 14 is preferably formed by a negative or positive photosensitive resin film. The organic film 14 may be formed by a polyimide film, a polyamide film, a polybenzoxazole film or an acrylic film. The thickness of the organic film 14 may be between 5 μm and 50 μm.

The first inorganic film 21 covers the organic film 14. In this embodiment, the first inorganic film 21 is formed by an inorganic conductor film (for example, a metal film), and has a modulus of elasticity greater than a modulus of elasticity of the organic film 14. The first inorganic film 21 may also be a rewiring electrically connected to at least one of the multiple wirings 10 on the organic film 14. FIG. 17 shows an example of a form in which the first inorganic film 21 includes a pad portion 21A and a wire portion 21B.

The pad portion 21A is formed to be shaped as a polygon (a quadrilateral in this embodiment) having a larger size in the plan view. The wire portion 21B has a size smaller than the size of the pad portion 21A in the plan view, and selectively routes wires in a linear form from the pad portion 21A to a region other than the pad portion 21A.

The first inorganic film 21 may have a single-layer structure formed by one single metal film or a laminated structure including multiple metal films. The first inorganic film 21 may include at least one of a Ti film, a TiN film, a W film, an Al film, a Cu film, an Al alloy film, a Cu alloy film and a conductive polysilicon film.

The second inorganic film 22 covers the first inorganic film 21 on the organic film 14. The second inorganic film 22 is formed by an inorganic insulating film, and has a modulus of elasticity greater than a modulus of elasticity of the organic film 14. The second inorganic film 22 may have a single-layer structure formed by one single inorganic insulating film or a laminated structure including multiple inorganic insulating films. The second inorganic film 22 may include at least one of a silicon oxide film and a silicon nitride film. The second inorganic film 22 may have a thickness greater than the thickness of the first inorganic film 21. The second inorganic film 22 may also have a thickness less than the thickness of the first inorganic film 21.

The opening 30 is formed in the second inorganic film 22 to expose the first inorganic film 21 (inorganic conductor film). In this embodiment, the opening 30 is formed as a pad opening exposing the pad portion 21A of the first inorganic film 21. In this embodiment, the opening 30 exposes a region surrounded by the periphery of the pad portion 21A at a distance inwardly from the periphery of the pad portion 21A in the plan view. In this embodiment, the opening 30 is defined to be shaped as a polygon (a quadrilateral in this embodiment) in the plan view.

The opening 30 has a wall surface 31 extending along the periphery of the pad portion 21A. The wall surface 31 includes first to fourth wall surfaces 31A to 31D. Similar to the electronic device 1A, the opening 30 has a portion curved in a wavy line shape in at least one of the first to fourth wall surfaces 31A to 31D. In this embodiment, the opening 30 has a portion curved in a wavy line shape in all of the first to fourth wall surfaces 31A to 31D. That is, the wall surface 31 of the opening 30 entirely and globally curves in a wavy line shape in the plan view. The structure of the opening 30 (the first to fourth wall surfaces 31A to 31D) is the same as that of the electronic device 1A, and specific details thereof are omitted herein.

The thickness gradually decreasing portion 36 is formed around the opening 30 in the second inorganic film 22. In this embodiment, the thickness gradually decreasing portion 36 is formed in a portion of the second inorganic film 22 covering the first inorganic film 21, and has a thickness less than the thickness of a portion covering the region other than the first inorganic film 21 in the second inorganic film 22.

The electronic device 1C may also include a main surface electrode (metal film) covering the second main surface 4 of the chip 2, specifically depending on specifications of the functional device 63. In this case, the main surface electrode may be electrically connected to the functional device 63.

The electronic device 1C is manufactured by modifying the structure on two sides of the chip 2 and the materials of the organic film 14, the first inorganic film 21 and the second inorganic film 22 in the method of manufacturing the electronic device 1A. As described above, the method of manufacturing the electronic device 1C can also provide the same effects as the effects of the method of manufacturing the electronic device 1A. Moreover, the electronic device 1C can also provide the same effects as the electronic device 1A. The protruding portion 62 of the second embodiment may also be applied to the opening 30 of the electronic device 1C.

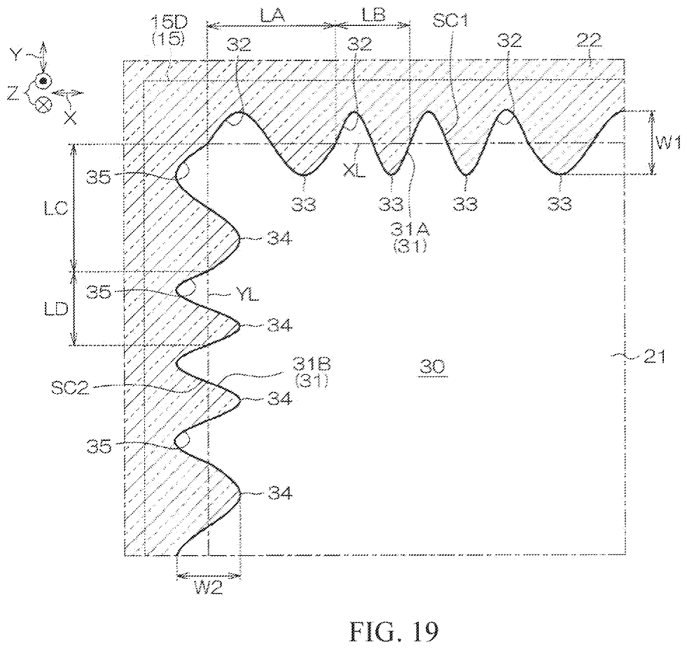

Variations examples of the opening 30 applied to the embodiments are to be illustrated below. FIG. 19 shows an enlarged plan view of a main portion of the opening of a first variation example. In the embodiments, the first wall surface 31A (third side surface 5C) curved in a wavy line shape at the constant first wavelength L1 and the second wall surface 31B (fourth side surface 5D) curved in a wavy line shape at the constant second wavelength L2 are depicted.

However, as shown in FIG. 19, either or both of the first wall surface 31A and the third side surface 5C may also have multiple (two or more) portions curved in wavy line shapes at wavelengths different from each other. FIG. 19 shows an example of a form in which the first wall surface 31A (third side surface 5C) includes a portion curved in a wavy line shape at a longer first wavelength LA and a portion curved in a wavy line shape at a second wavelength LB shorter than the first wavelength LA. The layouts (positions, ranges and lengths) of the first wavelength LA and the second wavelength LB may be designed as desired. The first wavelength LA and the second wavelength LB may be adjusted within a numeral range (between 5 μm and 100 μm) the same as that of the first wavelength L1.

Similarly, either or both of the second wall surface 31B and the fourth side surface 5D may also have multiple (two or more) portions curved in wavy line shapes at wavelengths different from each other. FIG. 19 shows an example of a form in which the second wall surface 31B (fourth side surface 5D) includes a portion curved in a wavy line shape at a longer third wavelength LC and a portion curved in a wavy line shape at a fourth wavelength LD shorter than the third wavelength LC. The layouts (positions, ranges and lengths) of the third wavelength LC and the fourth wavelength LD may be designed as desired. The third wavelength LC and the fourth wavelength LD may be adjusted within a numeral range (between 5 μm and 100 μm) the same as that of the second wavelength L2.

The third wavelength LC may be longer than first wavelength LA or may be shorter than the first wavelength LA. The third wavelength LC may also be substantially equal to the first wavelength LA. The third wavelength LC may be longer than second wavelength LB or may be shorter than the second wavelength LB. The third wavelength LC may also be substantially equal to the second wavelength LB.

The fourth wavelength LD may be longer than first wavelength LA or may be shorter than the first wavelength LA. The fourth wavelength LD may also be substantially equal to the first wavelength LA. The fourth wavelength LD may be longer than second wavelength LB or may be shorter than the second wavelength LB. The fourth wavelength LD may also be substantially equal to the second wavelength LB. The size relations of the first to fourth wavelengths LA to LD may be combined as desired.

At least one of the first to fourth wall surfaces 31A to 31D may also have three or more portions curved in wavy line shapes at wavelengths different from each other. Moreover, a structure in which the first wall surface 31A and/or the third side surface 5C has multiple wavelengths, and the second wall surface 31B and/or the fourth side surface has only one wavelength (the second wavelength L2) may be used. In contrast, a structure in which the first wall surface 31A and/or the third side surface 5C has only one wavelength (the first wavelength L1), and the second wall surface 31B and/or the fourth side surface 5D has two or more wavelengths may be used.

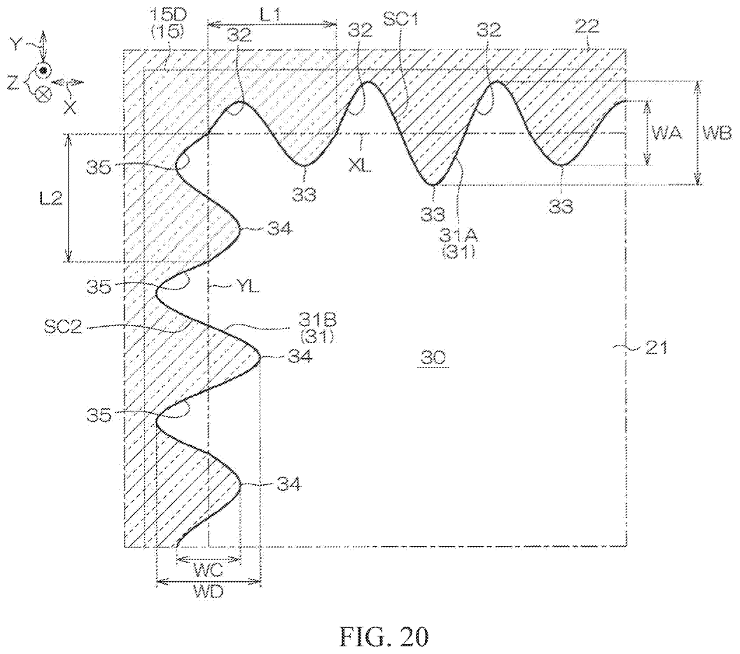

FIG. 20 shows an enlarged plan view of a main portion of the opening 30 of a second variation example. In the embodiments, the first wall surface 31A (third side surface 5C) curved in a wavy line shape at the constant first amplitude W1 and the second wall surface 31B (fourth side surface 5D) curved in a wavy line shape at the constant second amplitude W2 are depicted.

However, as shown in FIG. 20, either or both of the first wall surface 31A and the third side surface 5C may also have multiple (two or more) portions curved in wavy line shapes at amplitudes different from each other. FIG. 20 shows an example of a form in which the first wall surface 31A (third side surface 5C) includes a portion curved in a wavy line shape at a wider first amplitude WA and a portion curved in a wavy line shape at a second amplitude WB narrower than the first amplitude WA. The layouts (positions, ranges and widths) of the first amplitude WA and the second amplitude WB may be designed as desired. The first amplitude WA and the second amplitude WB may be adjusted within a numeral range (between 1 μm and 50 μm) the same as that of the first amplitude W1.

Similarly, either or both of the second wall surface 31B and the fourth side surface 5D may also have multiple (two or more) portions curved in wavy line shapes at amplitudes different from each other. FIG. 20 shows an example of a form in which the second wall surface 31B (fourth side surface 5D) includes a portion curved in a wavy line shape at a wider third amplitude WC and a portion curved in a wavy line shape at a fourth amplitude WD narrower than the third amplitude WC. The layouts (positions, ranges and widths) of the third amplitude WC and the fourth amplitude WD may be designed as desired. The third amplitude WC and the fourth amplitude WD may be adjusted within a numeral range (between 1 μm and 50 μm) the same as that of the second amplitude W2.

The third amplitude WC may be greater than the first amplitude WA or be less than the first amplitude WA. The third amplitude WC may also be substantially equal to the first amplitude WA. The third amplitude WC may be greater than the second amplitude WB or be less than the second amplitude WB. The third amplitude WC may also be substantially equal to the second amplitude WB.

The fourth amplitude WD may be greater than the first amplitude WA or be less than the first amplitude WA. The fourth amplitude WD may also be substantially equal to the first amplitude WA. The fourth amplitude WD may be greater than the second amplitude WB or be less than the second amplitude WB. The fourth amplitude WD may also be substantially equal to the second amplitude WB. The size relations of the first to fourth amplitudes WA to WD may be combined as desired.

At least one of the first to fourth wall surfaces 31A to 31D may also have three or more portions curved in wavy line shapes at amplitudes different from each other. Moreover, a structure in which the first wall surface 31A and/or the third side surface 5C has multiple amplitudes, and the second wall surface 31B and/or the fourth side surface has only one amplitude (the second amplitude W2) may be used. In contrast, a structure in which the first wall surface 31A and/or the third side surface 5C has only one amplitude (the first amplitude W1), and the second wall surface 31B and/or the fourth side surface 5D has multiple amplitudes may be used.

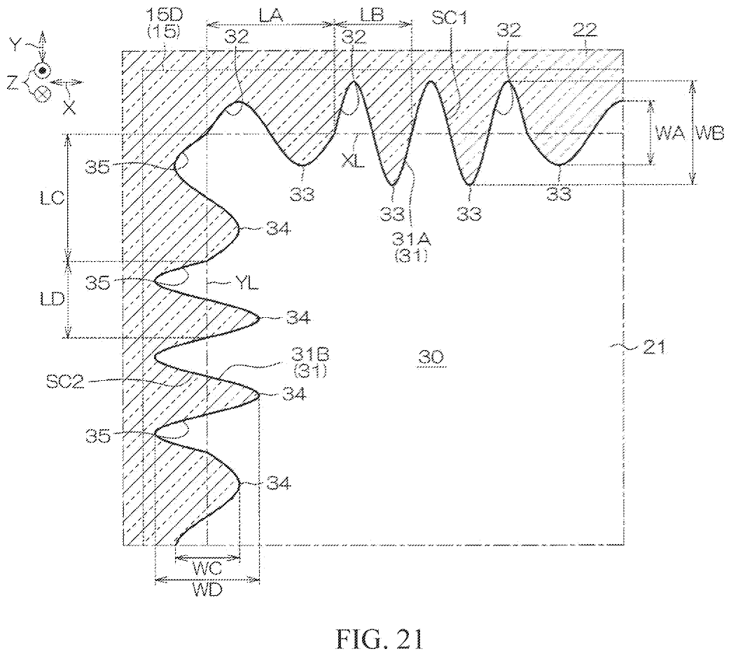

FIG. 21 shows an enlarged plan view of a main portion of the opening 30 of a third variation example. As shown in FIG. 21, the opening 30 may also have a form formed by a combination of the opening 30 of the first variation example and the opening of the second variation example.

That is, either or both of the first wall surface 31A and the third side surface 5C may have multiple (two or more) portions curved in wavy line shapes at wavelengths different from each other, and multiple (two or more) portions curved in wavy line shapes at amplitudes different from each other. That is, either or both of the second wall surface 31B and the fourth side surface 5D may have multiple (two or more) portions curved in wavy line shapes at wavelengths different from each other, and multiple (two or more) portions curved in wavy line shapes at amplitudes different from each other.

A structure in which the first wall surface 31A and/or the third side surface 5C has multiple wavelengths and multiple amplitudes, and the second wall surface 31B and/or the fourth side surface 5D has only one wavelength (the second wavelength L2) and only one amplitude (the second amplitude W2) may be used. In contrast, a structure in which the first wall surface 31A and/or the third side surface 5C has only one wavelength (the first wavelength L1) and only one amplitude (the first amplitude W1), and the second wall surface 31B and/or the fourth side surface 5D has multiple wavelengths and multiple amplitudes may also be used.

The various embodiments may be implemented by further using other forms. In the first and second embodiments, the second inorganic film 22 serves as an infrared cutoff filter film that selectively attenuates the fourth wavelength region λ4 of infrared light, and covers the first to third color filter films 15A to 15C. Moreover, the second inorganic film 22 may also serve as a red light cutoff filter film that selectively attenuates the first wavelength region λ1 of red light, and selectively covers the color filter film 15 (the second to fourth color filter films 15B to 15D) other than the first color filter film 15A.

Moreover, the second inorganic film 22 may also serve as a green light cutoff filter film that selectively attenuates the second wavelength region λ2 of green light, and selectively covers the color filter film 15 (the first, third and fourth color filter films 15A, 15C and 15D) other than the second color filter film 15B. Moreover, the second inorganic film 22 may also serve as a blue light cutoff filter film that selectively attenuates the third wavelength region λ3 of blue light, and selectively covers the color filter film 15 (the first, second and fourth color filter films 15A, 15B and 15D) other than the third color filter film 15C.

In this embodiment, the opening 30 exposes a portion of the first inorganic film 21 covering the fourth color filter film 15D. However, the opening 30 may also selectively expose at least one of the first to fourth color filter films 15A to 15D. Moreover, the opening 30 may also selectively expose at least two of the first to fourth color filter films 15A to 15D. Moreover, the opening 30 may also selectively expose at least three of the first to fourth color filter films 15A to 15D.

The features disclosed in the various embodiments can be appropriately combined with one another. That is, a form which includes at least two features of the features disclosed in the first to third embodiments may be used.

In the various embodiments, the first direction X and the second direction Y are set on the basis of the extension directions of the first to fourth side surfaces 5A to 5D of the chip 2. However, provided that an intersecting (orthogonal) relation is maintained, the first direction X and the second direction Y may be set to be independent from the extension directions of the first to fourth side surfaces 5A to 5D.

Examples of the features extracted from the detailed description and the drawings of the present application are given below. In the description below, alphabets and numerals given in the parentheses represent the corresponding constituents in the embodiments; however, these alphabets and numerals are not for limiting the scope of the clauses to the implementation details of the embodiments. The term “electronic device” related in the clauses below may also be replaced by “illuminance sensor”, “semiconductor light receiving apparatus” or “semiconductor apparatus” according to requirements.

[A1] An electronic device (1A, 1B, 1C), including:
a first inorganic film (21); a second inorganic film (22), covering the first inorganic film (21); and
an opening (30), formed in the second inorganic film (22) to partially expose the first inorganic film (21), wherein the opening has a wall surface (31, 31A to 31D) curved in a wavy line shape in a plan view.

[A2] The electronic device (1A, 1B, 1C) of A1, further including an organic film (14), wherein the first inorganic film (21) directly covers the organic film (14).

[A3] The electronic device (1A, 1B, 1C) of A2, wherein the first inorganic film (21) is thinner than the organic film (14).

[A4] The electronic device (1A, 1B, 1C) of A2 or A3, further including:
a chip (2);
a functional device (7, 7A to 7D, 63), formed on the chip (2); and
an interlayer insulating film (9), covering the functional device (7, 7A to 7D, 63), wherein the organic film (14) covers the interlayer insulating film (9).

[A5] The electronic device (1A, 1B, 1C) of any one of A2 to A4, wherein the organic film (14) includes a transparent resin film (15, 16), and the first inorganic film (21) covers the transparent resin film (15, 16).

[A6] The electronic device (1A, 1B, 1C) of any one of A1 to A5, wherein the wall surface (31, 31A to 31D) includes a first wall surface (31, 31A, 31C) extending in a first direction (X) in the plan view and a second wall surface (31, 31B, 31D) extending in a second direction (Y) intersecting the first direction (X) in the plan view, the first wall surface (31, 31A, 31C), in the plan view, includes a first recess portion (32) recessed toward one side in the second direction (Y) and a first protrusion portion (33) protruding toward the other side in the second direction (Y), and the second wall surface (31, 31B, 31D), in the plan view, includes a second recess portion (34) recessed toward one side in the first direction (X) and a second protrusion portion (35) protruding toward the other side in the first direction (X).

[A7] The electronic device (1A, 1B, 1C) of A6, wherein the first wall surface (31, 31A, 31C) has an end formed by the first recess portion (32), and the second wall surface (31, 31B, 31D) has an end formed by the second recess portion (34) and connected to the end of the first wall surface (31, 31A, 31C).

[A8] The electronic device (1A, 1B, 1C) of any one of A1 to A7, wherein the wall surface (31, 31A to 31D) has a constant wavelength (L1, L2) in the plan view.

[A9] The electronic device (1A, 1B, 1C) of any one of A1 to A8, wherein the wall surface (31, 31A to 31D) has a constant amplitude (W1, W2) in the plan view in the plan view.

[A10] The electronic device (1A, 1B, 1C) of any one of A1 to A9, wherein the second inorganic film (22) is thicker than the first inorganic film (21).

[A11] The electronic device (1A, 1B, 1C) of any one of A1 to A10, wherein the second inorganic film (22) has a thickness between 1 μm and 15 μm.

[A12] The electronic device (1A, 1B, 1C) of any one of A1 to A11, wherein the second inorganic film (22) includes a thickness gradually decreasing portion (36) disposed in a portion located around the opening (30) and having a film thickness gradually decreased toward the opening (30).

[A13] The electronic device (1A, 1B, 1C) of any one of A1 to A12, wherein the second inorganic film (22) has a laminated structure including a plurality of inorganic films.

[A14] The electronic device (1A, 1B, 1C) of any one of A1 to A13, wherein the second inorganic film (22) has a laminated structure including a silicon oxide film and a titanium oxide film.

[A15] The electronic device (1A, 1B, 1C) of any one of A1 to A14, wherein the second inorganic film (22) is formed as an optical filter film.

[A16] The electronic device (1A, 1B, 1C) of any one of A1 to A15, wherein the second inorganic film (22) includes a protruding portion (62) that protrudes toward an opposite side of the first inorganic film (21) in a portion defining the wall surface (31, 31A to 31D).

[A17] A method of fabricating an electronic device (1A, 1B, 1C), including:
forming a resist film (50) having a sidewall (51, 51A to 51D) curved in a wavy line shape in a plan view to partially cover a first inorganic film (21);
forming a second inorganic film (22) covering the first inorganic film (21) and the resist film (50) to expose at least a portion of the sidewall (51, 51A to 51D) of the resist film (50); and
removing the resist film (50) to form an opening (30) in the second inorganic film (22), wherein the opening (30) has a wall surface (31, 31A to 31D) curved in a wavy line shape in the plan view and partially exposes the first inorganic film (21).

[A18] The method of fabricating an electronic device (1A, 1B, 1C) of A17, wherein the removing of the resist film (50) includes immersing the resist film (50) in a resist stripping solution.

[A19] The method of fabricating an electronic device (1A, 1B, 1C) of A17 or A18, wherein the removing of the resist film (50) includes applying an ultrasonic wave to the resist film (50).

[A20] The method of fabricating an electronic device (1A, 1B, 1C) of any one of A17 to A19, further including forming the first inorganic film (21) on an organic film (14).

The embodiments have been described in detail as above. However, these embodiments are merely for better illustrating specific examples of the technical contents, and the disclosure is not limited to interpretations based on these specific examples. Therefore, the scope of the disclosure should be defined by the appended claims.

1. An electronic device, comprising:
a first inorganic film;
a second inorganic film, covering the first inorganic film; and
an opening, formed in the second inorganic film to partially expose the first inorganic film, wherein the opening has a wall surface curved in a wavy line shape in a plan view.

2. The electronic device of claim 1, further comprising an organic film, wherein the first inorganic film directly covers the organic film.

3. The electronic device of claim 2, wherein the first inorganic film is thinner than the organic film.

4. The electronic device of claim 3, further comprising:
a chip;
a functional device, formed on the chip; and
an interlayer insulating film, covering the functional device, wherein the organic film covers the interlayer insulating film.

5. The electronic device of claim 4, wherein the organic film includes a transparent resin film, and the first inorganic film covers the transparent resin film.

6. The electronic device of claim 1, wherein
the wall surface includes a first wall surface extending in a first direction in the plan view and a second wall surface extending in a second direction intersecting the first direction in the plan view,
the first wall surface, in the plan view, includes:
a first recess portion recessed toward one side in the second direction; and
a first protrusion portion protruding toward another other side in the second direction, and
the second wall surface, in the plan view, includes:
a second recess portion recessed toward one side in the first direction and
a second protrusion portion protruding toward another other side in the first direction.

7. The electronic device of claim 6, wherein the first wall surface has an end formed by the first recess, and the second wall surface has an end formed by the second recess and connected to the end of the first wall surface.

8. The electronic device of claim 1, wherein the wall surface has a constant wavelength in the plan view.

9. The electronic device of claim 1, wherein the wall surface has a constant amplitude in the plan view.

10. The electronic device of claim 1, wherein the second inorganic film is thicker than the first inorganic film.

11. The electronic device of claim 1, wherein the second inorganic film has a thickness between 1 μm and 15 μm.

12. The electronic device of claim 1, wherein the second inorganic film includes a thickness gradually decreasing portion disposed in a portion located around the opening and having a film thickness gradually decreased toward the opening.

13. The electronic device of claim 1, wherein the second inorganic film has a laminated structure including a plurality of inorganic films.

14. The electronic device of claim 1, wherein the second inorganic film has a laminated structure including a silicon oxide film and a titanium oxide film.

15. The electronic device of claim 1, wherein the second inorganic film is formed as an optical filter film.

16. The electronic device of claim 1, wherein the second inorganic film includes a protruding portion that protrudes toward an opposite side of the first inorganic film in a portion defining the wall surface.

17. A method of fabricating an electronic device, comprising:
forming a resist film having a sidewall curved in a wavy line shape in a plan view to partially cover a first inorganic film;
forming a second inorganic film covering the first inorganic film and the resist film to expose at least a portion of the sidewall of the resist film; and
removing the resist film to form an opening in the second inorganic film, wherein the opening has a wall surface curved in a wavy line in the plan view and partially exposing the first inorganic film.

18. The method of claim 17, wherein the removing of the resist film includes immersing the resist film in a resist stripping solution.

19. The method of claim 17, wherein the removing the resist film includes applying an ultrasonic wave to the resist film.

20. The method of claim 17, further comprising forming the first inorganic film on an organic film.
